(19) United States
(12) Patent Application Publication
(10) Pub. No.: US 2026/0173511 A1
(43) Pub. Date: Jun. 18, 2026

(54) SEMICONDUCTOR DEVICE

(71) Applicant: Samsung Electronics Co., Ltd., Suwon-si (KR)

(72) Inventors: Dahye KIM, Suwon-si (KR); Juhun PARK, Suwon-si (KR); Daihong HUH, Suwon-si (KR)

(73) Assignee: Samsung Electronics Co., Ltd., Suwon-si (KR)

(21) Appl. No.: 19/270,739

(22) Filed: Jul. 16, 2025

(30) Foreign Application Priority Data
Dec. 16, 2024 (KR) 10-2024-0187383

(51) Int. Cl. H10D 84/83; H10D 30/00; H10D 30/01; H10D 62/10; H10D 62/13; H10D 64/23; H10D 84/01

(52) U.S. Cl. CPC H10D 84/832; H10D 30/0198; H10D 62/116; H10D 62/151; H10D 64/256; H10D 84/013; H10D 84/0149; H10D 84/8312; H10D 30/502; H10D 62/121

(57) ABSTRACT

Provided is a semiconductor device including a first active pattern including a plurality of first sheets spaced apart from each other, a second active pattern above the first active pattern and including a plurality of second sheets spaced apart from each other in the first direction, a first source/drain pattern connected to the first active pattern in a second direction, a second source/drain pattern above the first source/drain pattern and connected to the second active pattern in the second direction, a gate electrode extending in a third direction and surrounding the first active pattern and the second active pattern, and a fence layer surrounding the first source/drain pattern. The first source/drain pattern surrounded by the fence layer has a first width in the third direction, and the second source/drain pattern spaced apart from the fence layer has a second width greater than the first width in the third direction.

### CROSS-REFERENCE TO RELATED APPLICATIONS

This application claims the benefit of Korean Patent Application No. 10-2024-0187383, filed on Dec. 16, 2024, in the Korean Intellectual Property Office, the disclosure of which is incorporated herein by reference in its entirety.

### BACKGROUND

Example embodiments relate to a semiconductor device.

As an option for raising the density of an integrated circuit device, multi-gate transistors have been suggested, in which a fin-shaped or nanowire-shaped silicon body is formed on a substrate and gates are formed on a surface of the silicon body.

Meanwhile, according to the scaling down of the multi-gate transistor, a three-dimensional stacked semiconductor device in which a lower nanosheet transistor and an upper nanosheet transistor are stacked is introduced.

### SUMMARY

An aspect provides a semiconductor device in which a degree of integration is enhanced.

Another aspect provides a semiconductor device in which a width of a source/drain pattern is extended.

Example embodiments are not limited to the technical goals described above, and other unstated technical goals may be made apparent to those skilled in the art from the following description.

According to an aspect, there is provided a semiconductor device including a first active pattern on a substrate, the first active pattern including a plurality of first sheets, the plurality of first sheets spaced apart from each other in a first direction, the first direction intersecting an upper surface of the substrate; a second active pattern above the first active pattern, the second active pattern including a plurality of second sheets, the plurality of second sheets spaced apart from each other in the first direction; a first source/drain pattern connected to the first active pattern in a second direction, the second direction intersecting the first direction; a second source/drain pattern above the first source/drain pattern and connected to the second active pattern in the second direction; a gate electrode surrounding the first active pattern and the second active pattern and extending in a third direction, the third direction intersecting the first direction and the second direction; and a fence layer surrounding at least a portion of the first source/drain pattern. The at least a portion of the first source/drain pattern surrounded by the fence layer has a first width in the third direction, and the second source/drain pattern spaced apart from the fence layer has a second width in the third direction, the second width greater than the first width.

According to another aspect, there is provided a semiconductor device including a first active pattern on a substrate, the first active pattern including a plurality of first sheets, the plurality of first sheets spaced apart from each other in a first direction intersecting an upper surface of the substrate; a second active pattern above the first active pattern, the second active pattern including a plurality of second sheets, the plurality of second sheets spaced apart from each other in the first direction; a first source/drain pattern connected to the first active pattern in a second direction, the second direction intersecting the first direction; a second source/drain pattern above the first source/drain pattern and connected to the second active pattern in the second direction; a gate electrode surrounding the first active pattern and the second active pattern and extending in a third direction, the third direction intersecting with the first direction and the second direction; and a fence layer surrounding at least a portion of the first source/drain pattern, the fence layer including a fence end portion spaced apart from the second source/drain pattern. At least a portion of the second source/drain pattern may be spaced apart from the fence end portion in the first direction and may overlap with the fence end portion in the first direction.

According to another aspect, there is provided a semiconductor device including a first active pattern on a substrate, the first active pattern including a plurality of first sheets, the plurality of first sheets spaced apart from each other in a first direction, the first direction intersecting an upper surface of the substrate; a second active pattern above the first active pattern, the second active pattern including a plurality of second sheets, the plurality of second sheets spaced apart from each other in the first direction; a first source/drain pattern connected to the first active pattern in a second direction, the second direction intersecting the first direction; a second source/drain pattern above the first source/drain pattern and connected to the second active pattern in the second direction; a gate electrode surrounding the first active pattern and the second active pattern and extending in a third direction, the third direction intersecting the first direction and the second direction; and a fence layer surrounding the first source/drain pattern and spaced apart from the second source/drain pattern, the fence layer non-overlapping with the second source/drain pattern in the third direction.

According to an aspect of the present disclosure, there is provided a method of forming a semiconductor device, the method including forming a dummy gate and a dummy capping layer such that the dummy gate and the dummy capping layer intersect a stacked structure, the stacked structure above a fin structure on a substrate; forming a pre-spacer on the dummy gate, the dummy capping layer, and at least a portion of the stacked structure; patterning the stacked structure using the dummy gate and the dummy capping layer as a mask such that a region of the fin structure is exposed and such that a fence is formed from the pre-spacer; forming a first source/drain pattern on the region of the fin structure exposed by the patterning such that a growth of the first source/drain pattern, in a horizontal direction, is constrained by the fence; and forming a second source/drain pattern above the first source/drain pattern.

According to some aspects, the stacked structure may include a plurality of first sheet layers and a plurality of sacrificial layers in an alternating stack on the fin structure, and the patterning the stacked structure may include a first patterning, wherein portions of the first sheet layers and the plurality of sacrificial layers are removed such that the region of the fin structure is exposed, and a second patterning, wherein an upper portion of the region of the fin structure exposed in the first patterning is removed.

According to some aspects, a width of the first source/drain pattern, in the horizontal direction, is less than a width of the second source/drain pattern in the horizontal direction.

According to some aspects, the second source/drain pattern includes a first portion which overlaps with the first source/drain pattern in a vertical direction and a second portion that overlaps with the fence in the vertical direction.

According to some aspects, the method further comprises forming an interlayer insulating layer in a space between the first source/drain pattern and the second source/drain pattern.

According to some aspects, the forming the first source/drain pattern includes forming a first source/drain layer including a first impurity at a first concentration; and a second source/drain layer including the first impurity at a second concentration, the second concentration greater than the first concentration.

According to some aspects, the length of the first source drain in a second horizontal direction is the same as a length of the second source/drain pattern in the second direction.

Details of example embodiments are included in the detailed description and drawings.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is an example diagram showing a schematic layout of a semiconductor device according to some example embodiments;

FIG. 2 is an example diagram for illustrating a cross-section taken along line A-A of FIG. 1;

FIG. 3 is an example diagram for illustrating a cross-section taken along line B-B of FIG. 1;

FIG. 4 is an example diagram for illustrating a cross-section taken along line C-C of FIG. 1;

FIG. 5 is an example enlarged view showing part P of FIG. 3;

FIG. 6 is an example enlarged view showing part Q of FIG. 2; and

FIGS. 7 to 29 are example diagrams of intermediate operations for illustrating a method of manufacturing a semiconductor device according to some example embodiments.

### DETAILED DESCRIPTION

Before describing example embodiments in detail, the words and terminologies used in the specification and claims are not to be construed as limited to common or dictionary meanings but construed as meanings and concepts coinciding with the technical idea of the present disclosure under the principle that the inventor(s) may appropriately define the concept of the terms to explain his or her own invention in the best manner. Therefore, the example embodiments described in the specification and the configurations illustrated in the drawings are no more than the preferred example embodiments of the present disclosure and do not fully cover the technical idea of the present disclosure. Accordingly, it should be understood that there may be various equivalents and modification examples that may replace the example embodiments when this application is filed.

In the following description, a singular expression includes a plural expression unless apparently otherwise defined by context. It should be understood that terms such as “comprise or include” and “form” are intended to indicate the presence of a feature, a number, a step, an operation, an element, a component, or a combination thereof described in the specification and not intended to exclude the possibility of the presence or addition of one or more other features, numbers, steps, operations, elements, components, or combinations thereof in advance.

In the present disclosure, a singular expression includes a plural expression unless apparently otherwise defined by context. In addition, although the numerical descriptors, such as first and second, may be used to describe various elements, the numerical descriptors are used to distinguish one element from another and these elements are not otherwise limited by the numerical descriptors. Within the scope of the present disclosure, a first element may be referred to as a second element, and similarly, a second element may be referred to as a first element. Further, in the accompanying drawings, the shapes, sizes, and the like of elements may be exaggerated for clearer description.

In addition, expressions such as upper side, upper portion, above, lower side, lower portion, below, side surface, front surface, and rear surface are represented hereinafter with respect to a direction illustrated in a drawing and may be represented otherwise when the direction of a corresponding object changes. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Hereinafter, example embodiments of the present disclosure will be described with reference to the accompanying drawings.

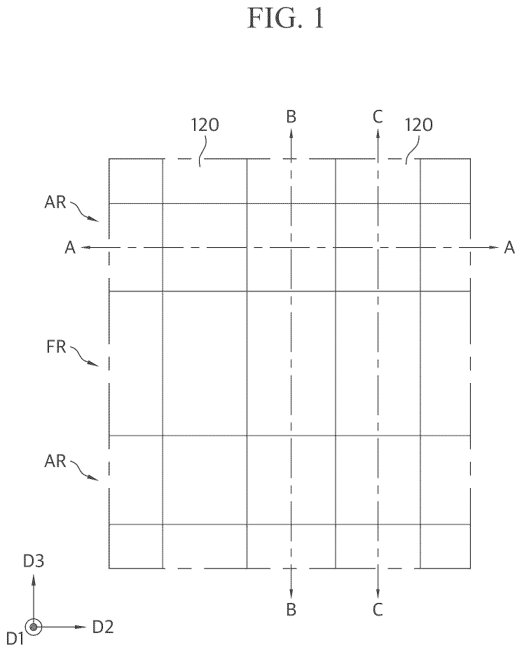

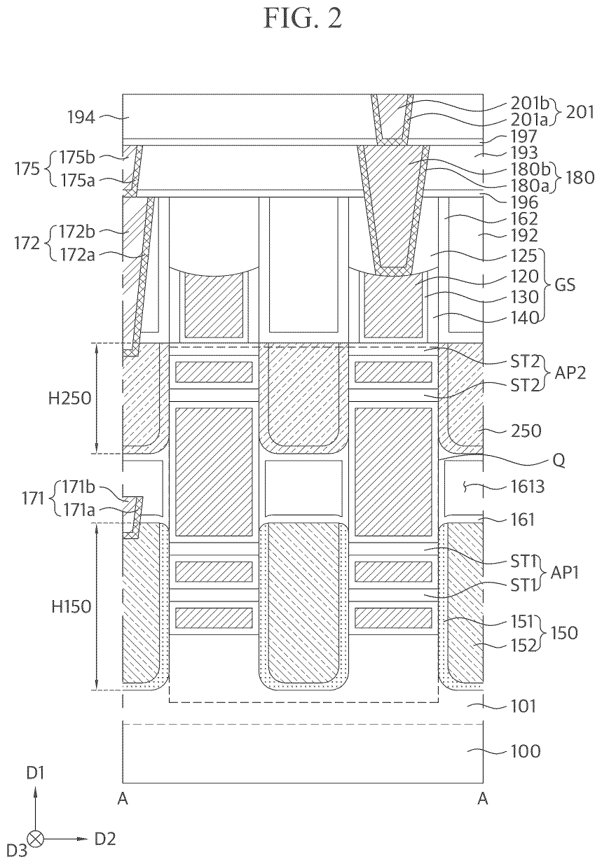

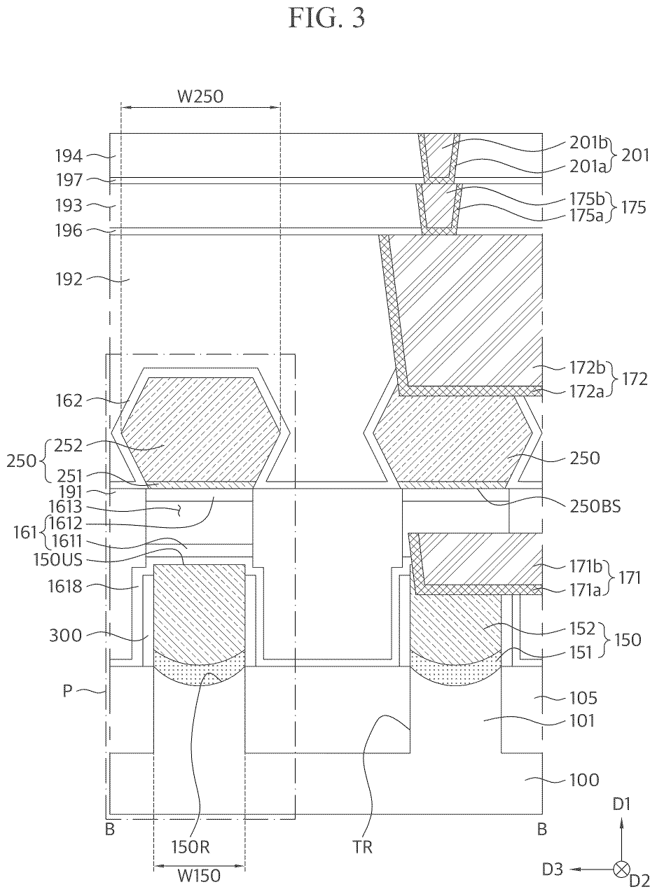

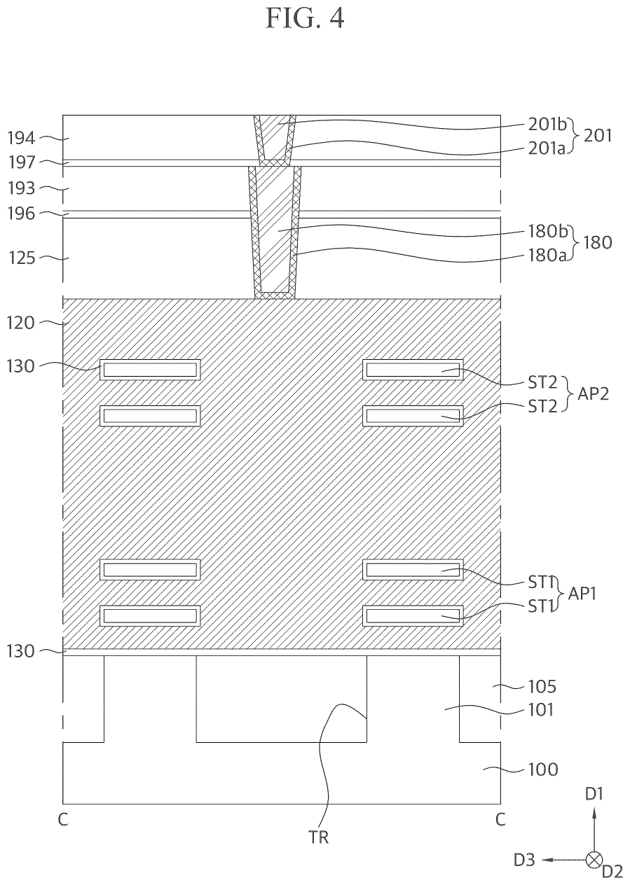

FIG. 1 is an example diagram showing a schematic layout of a semiconductor device according to some example embodiments. FIG. 2 is an example diagram for illustrating a cross-section taken along line A-A of FIG. 1, and FIG. 3 is an example diagram for illustrating a cross-section taken along line B-B of FIG. 1. FIG. 4 is an example diagram for illustrating a cross-section taken along line C-C of FIG. 1.

Referring to FIGS. 1 to 4, a semiconductor device according to some example embodiments may include a substrate 100, a fin-type pattern 101, a first active pattern AP1, a second active pattern AP2, a gate structure GS, a first source/drain pattern 150, a second source/drain pattern 250, and a fence layer 300.

According to some example embodiments, the substrate 100 may include an active region AR and a field region FR. The active region AR and the field region FR may extend in a second direction D2. The active region AR and the field region FR may be disposed alternately with each other in a third direction D3. For example, the active region AR may be disposed between the field regions FR in the third direction D3. The field region FR may be disposed between the active regions AR in the third direction D3. In these cases, each of the second direction D2 and the third direction D3 may refer to a direction parallel to the substrate 100 and intersecting a first direction D1. The first direction D1 may refer to a direction perpendicular to the substrate 100. The second direction D2 may refer to an extending direction of the active region AR and the field region FR. The third direction D3 may refer to a direction in which the active region AR and the field region FR are disposed alternately.

According to some example embodiments, the field region FR may be defined by a trench TR but is not limited thereto. The field region FR may have a shallow trench isolation (STI) structure. However, example embodiments are not limited thereto. For example, the field region FR may also be defined by a deep trench.

According to some example embodiments, an element isolation layer (not shown) may be disposed around the active regions AR spaced apart from each other. In these cases, a portion of the element isolation layer between two adjacent active regions AR may be the field region FR. For example, a portion where a channel region of a transistor, which may be one example of the semiconductor device, is formed may be an active region, and a portion dividing the channel region of the transistor formed in the active region may be a field region. Alternatively, the active region may be a portion where a fin-type pattern or a nanosheet used as the channel region of the transistor is formed, and the field region may be a portion where the fin-type pattern or the nanosheet used as the channel region is not formed.

According to some example embodiments, the substrate 100 may be semiconductor substrate. For example, the substrate 100 may include at least one of an elemental semiconductor or a compound semiconductor. In at least some examples, the substrate 100 may include at least one of a bulk silicon, a silicon-on-insulator (SOI), polycrystalline silicon, silicon germanium, silicon germanium on insulator (SGOI), indium antimonide, lead telluride, indium arsenide, indium phosphide, gallium arsenide, or gallium antimonide, but is not limited thereto.

According to some example embodiments, the fin-type pattern 101 may be disposed on the active region AR of the substrate 100. The fin-type pattern 101 may protrude from the substrate 100. The fin-type pattern 101 may extend for a long distance in the second direction D2. The fin-type pattern 101 may also be formed by etching a portion of the substrate 100 and/or may include an epitaxial layer grown from the substrate 100. Thereby, the fin-type pattern 101 may include a same or different material as the substrate 100. The fin-type pattern 101 may include an elemental semiconductor material, such as silicon and/or germanium.

According to some example embodiments, the fin-type pattern 101 may include silicon (Si). For another example, the fin-type pattern 101 may include a compound semiconductor and may include, for example, group IV-IV compound semiconductor or group III-V compound semiconductor. The group IV-IV compound semiconductor may be, for example, a binary compound or a ternary compound, including at least two or more of carbon (C), silicon (Si), germanium (Ge), and tin (Sn), or a compound doped with a group IV element thereto. The group III-V compound semiconductor may be, for example, one of a binary compound, a ternary compound, and a quaternary compound, which are formed by bonding at least one of aluminum (Al), gallium (Ga), and indium (In) as a group III element and one of phosphorus (P), arsenic (As), and antimony (Sb) as a group V element. For example, the fin-type pattern 101 may include a semiconductor material. One of the elemental semiconductor material such as silicon or germanium, the group IV-IV compound semiconductor, or the group III-V compound semiconductor may be included.

According to some example embodiments, the first active pattern AP1 may be disposed in the active region AR of the substrate 100. The first active pattern AP1 may be disposed above the fin-type pattern 101. In some examples, the first active pattern AP1 may be an active pattern including at least one of a nanosheet or a nanowire. For example, the first active pattern AP1 may include a plurality of first sheets ST1. The plurality of first sheets ST1 may be disposed above the substrate 100. The plurality of first sheets ST1 may be disposed to be spaced apart from the substrate 100 in the first direction D1. The plurality of first sheets ST1 may be disposed to be spaced apart from each other in the first direction D1. The plurality of first sheets ST1 may extend in the second direction D2.

According to some example embodiments, in the second direction D2, the first active pattern AP1 may be disposed between the first source/drain patterns 150. The first active pattern AP1 may be electrically connected to the first source/drain pattern 150.

According to some example embodiments, the second active pattern AP2 may be disposed in the active region AR of the substrate 100. The second active pattern AP2 may be disposed above the first active pattern AP1. The second active pattern AP2 may be spaced apart from the first active pattern AP1 in the first direction D1. In some examples, the second active pattern AP2 may be an active pattern including at least one of a nanosheet or a nanowire. For example, the second active pattern AP2 may include a plurality of second sheets ST2. In other words, in at least some examples, the plurality of second sheets ST2 may be disposed above the plurality of first sheets ST1. The plurality of second sheets ST2 may be disposed to be spaced apart from each other in the first direction D1. The plurality of second sheets ST2 may extend in the second direction D2.

According to some example embodiments, in the second direction D2, the second active pattern AP2 may be disposed between the second source/drain patterns 250. The second active pattern AP2 may be connected to the second source/drain pattern 250.

For example, widths of the plurality of first sheets ST1 of the first active pattern AP1 and the plurality of second sheets ST2 of the second active pattern AP2 in the third direction D3 may be longer or shorter in proportion to a width of the fin-type pattern 101 in the third direction D3, which is disposed below the first active pattern AP1. It is illustrated that the widths of the plurality of first sheets ST1 of the first active pattern AP1 and the plurality of second sheets ST2 of the second active pattern AP2 in the third direction D3 are identical, but example embodiments are not limited thereto.

According to some example embodiments, the first active pattern AP1 and the second active pattern AP2 may include, for example, at least one of silicon or germanium, the elemental semiconductor materials. In addition, the first active pattern AP1 and the second active pattern AP2 may include a compound semiconductor for example, at least one of a group IV-IV compound semiconductor or group III-V compound semiconductor.

According to some example embodiments, the group IV-IV compound semiconductor may be, for example, at least one of a binary compound or a ternary compound, including at least two or more of carbon (C), silicon (Si), germanium (Ge), and tin (Sn), or a compound doped with a group IV element thereto.

According to some example embodiments, the group III-V compound semiconductor may be, for example, at least one of a binary compound, a ternary compound, or a quaternary compound, which are formed by bonding at least one of aluminum (Al), gallium (Ga), or indium (In) as a group III element and at least one of phosphorus (P), arsenic (As), or antimony (Sb) as a group V element.

According to some example embodiments, each of the first active pattern AP1 and the second active pattern AP2 may include an identical material to the fin-type pattern 101 or may also include a different material from the fin-type pattern 101. The fin-type pattern 101 may be a silicon fin-type pattern that includes silicon, and the first active pattern AP1 and the second active pattern AP2 may be silicon sheet patterns that include silicon. Each of the first active pattern AP1 and the second active pattern AP2 may not include a p-type impurity or an n-type impurity. The first active pattern AP1 and the second active pattern AP2 may include silicon alone.

FIG. 2 illustrates that the first active pattern AP1 and the second active pattern AP2 include two of the first sheets ST1 and two of the second sheets ST2, respectively, but example embodiments are not limited thereto. For example, each of the first active pattern AP1 and the second active pattern AP2 may include three or more sheets.

According to some example embodiments, a field insulating layer 105 may be disposed in the field region FR. The field insulating layer 105 may be disposed on the substrate 100. For example, the field insulating layer 105 may be disposed between the fin-type patterns 101 overlapping the first active pattern AP1 in the first direction D1 and another fin-type patterns 101 overlapping another first active pattern AP1 in the first direction D1. In other words, the field insulating layer 105 may be disposed on the substrate 100 not overlapping the first active pattern AP1 and the second active pattern AP2 in the first direction D1. The field insulating layer 105 may fill at least a portion of the trench TR formed on the substrate 100.

According to some example embodiments, the field insulating layer 105 may cover a sidewall of the fin-type pattern 101. An upper surface of the field insulating layer 105 may be disposed on the same plane as an upper surface of the fin-type pattern 101. Unlike the drawings, for another example, the field insulating layer 105 may cover only a portion of the sidewall of the fin-type pattern 101. In these cases, a portion of the fin-type pattern 101 may protrude more than the field insulating layer 105 in the first direction D1. For example, the field insulating layer 105 may include at least one of an oxide layer, a nitride layer, an oxynitride layer, or a combination layer thereof. The field insulating layer 105 is illustrated as a single layer, merely for convenience of description, but is not limited thereto.

According to some example embodiments, the gate structure GS may be disposed on the substrate 100. Each gate structure GS may extend in the third direction D3. The gate structures GS may be disposed to be spaced apart in the second direction D2. The gate structures GS may be adjacent to each other in the second direction D2.

According to some example embodiments, the gate structure GS may be disposed on the first active pattern AP1 and the second active pattern AP2. For example, the gate structure GS may intersect the first active pattern AP1 and the second active pattern AP2.

According to some example embodiments, the gate structure GS may surround the first active pattern AP1 and the second active pattern AP2. Specifically, a gate electrode 120 of the gate structure GS may surround the plurality of first sheets ST1 and the plurality of second sheets ST2.

FIG. 1 illustrates that the gate electrode 120 of the gate structure GS is disposed across the active region AR and the field region FR, but example embodiments are not limited thereto. For example, the gate structure GS may not extend continuously in the third direction D3 across two active regions AR spaced apart in the third direction D3 with the field region FR in between to be separated in the field region FR. In these cases, the gate structure GS extending in the third direction D3 and intersecting one active region AR and the gate structure GS extending in the third direction D3 and intersecting another active region AR may be spaced apart from each other in the third direction D3.

According to some example embodiments, the gate structure GS may include the gate electrode 120, a gate insulating layer 130, a gate spacer 140, and a gate capping layer 125.

According to some example embodiments, the gate electrode 120 may extend in the third direction D3. The gate electrode 120 may be disposed between the first source/drain patterns 150 adjacent to each other in the second direction D2. The gate electrode 120 may be disposed between the second source/drain patterns 250 adjacent to each other in the second direction D2.

According to some example embodiments, the gate electrode 120 may be formed above the fin-type pattern 101. The gate electrode 120 may intersect the fin-type pattern 101. The gate electrode 120 may surround the first active pattern AP1 and the second active pattern AP2.

According to some example embodiments, a portion of the gate electrode 120 may be disposed between the first sheets ST1 adjacent in the first direction D1 and between the second sheets ST2 adjacent in the first direction D1. In addition, a portion of the gate electrode 120 may be disposed between one of the first sheets ST1 and one of the second sheets ST2, which are adjacent in the first direction D1.

According to some example embodiments, the gate electrode 120 may include a conductive material, such as at least one of a metal, a metal alloy, a conductive metal nitride, a metal silicide, a doped semiconductor material, a conductive metal oxide, and a conductive metal oxynitride. In at least some embodiments, the conductive material may include a zero-band gap material, and/or a material doped to have an equivalent conductivity. For example, the gate electrode 120 may include, but is not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. The conductive metal oxide and the conductive metal oxynitride may include, but are not limited to, an oxidized form of the materials described above.

According to some example embodiments, the gate electrode 120 may be disposed at both sides of the first source/drain pattern 150 and at both sides of the second source/drain pattern 250 to be described below. The gate structure GS may be disposed at both sides of the first source/drain pattern 150 and at both sides of the second source/drain pattern 250 in the second direction D2.

As an example, all of the gate electrodes 120 disposed at both sides of the first source/drain pattern 150 may be a normal gate electrode used as a gate of a transistor. As another example, the gate electrode 120 disposed at one side of the first source/drain pattern 150 may be used as the gate of the transistor, while the gate electrode 120 disposed at another side of the first source/drain pattern 150 may be a dummy gate electrode.

According to some example embodiments, the gate insulating layer 130 may extend along the upper surface of the field insulating layer 105 and the upper surface of the fin-type pattern 101. The gate insulating layer 130 may surround the first active pattern AP1 and the second active pattern AP2. The gate insulating layer 130 may be disposed along perimeters of the first sheets ST1 and the second sheets ST2. The gate electrode 120 may be disposed on the gate insulating layer 130. The gate insulating layer 130 may be disposed between the gate electrode 120 and the first active pattern AP1. The gate insulating layer 130 may be disposed between the gate electrode 120 and the second active pattern AP2.

According to some example embodiments, a portion of the gate insulating layer 130 may be disposed between the first sheets ST1 adjacent in the first direction D1, between the second sheets ST2 adjacent in the first direction D1, and between the fin-type pattern 101 and the first sheets ST1, which are adjacent in the first direction D1. In addition, a portion of the gate insulating layer 130 may be disposed between one of the first sheets ST1 and one of the second sheets ST2, which are adjacent to each other in the first direction D1.

According to some example embodiments, the gate insulating layer 130 includes an insulator. For example, in some examples, the gate insulating layer 130 may include at least one of silicon oxide, silicon-germanium oxide, germanium oxide, silicon oxynitride, silicon nitride, or a high-permittivity material with a greater dielectric constant than silicon oxide. The high-permittivity material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

FIGS. 2 to 4 illustrate that the gate insulating layer 130 is a single layer, merely for convenience of description, but the example embodiments are not limited thereto. The gate insulating layer 130 may include a plurality of layers. The gate insulating layer 130 may also include an interfacial layer disposed between the first active pattern AP1 or the second active pattern AP2 and the gate electrode 120 and a high-permittivity insulating layer.

The semiconductor device according to some example embodiments may include a negative capacitance (NC) field-effect transistor (FET) using a negative capacitor. For example, the gate insulating layer 130 may include a ferroelectric material film having a ferroelectric property and a paraelectric material film having a paraelectric property.

According to some example embodiments, the ferroelectric material film may have negative capacitance, and the paraelectric material film may have positive capacitance. For example, when two or more capacitors are connected in series and a capacitance of each capacitor has a positive value, a total capacitance becomes less than the capacitance of each individual capacitor. In contrast, when at least one of capacitances of two or more capacitors connected in series has a negative value, a total capacitance may have a positive value and be greater than an absolute value of each individual capacitance.

According to some example embodiments, when the ferroelectric material film with negative capacitance and the paraelectric material film with positive capacitance are connected in series, a total capacitance value of the ferroelectric material film and the paraelectric material film connected in series may increase. Using the increasing total capacitance value, a transistor including the ferroelectric material film may have a subthreshold swing (SS) less than 60 millivolts/decade (mV/decade) at room temperature.

According to some example embodiments, the ferroelectric material film may have the ferroelectric property. The ferroelectric material film may include, for example, at least one of hafnium oxide, hafnium zirconium oxide, barium strontium titanium oxide, barium titanium oxide, or lead zirconium titanium oxide. Here, as an example, hafnium zirconium oxide may be a material doped with zirconium (Zr) to hafnium oxide. As another example, hafnium zirconium oxide may also be a compound of hafnium (Hf), zirconium (Zr), and oxygen (O).

According to some example embodiments, the ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). Depending on which ferroelectric material is included in the ferroelectric material film, a type of the dopant included in the ferroelectric material film may vary.

According to some example embodiments, when the ferroelectric material film includes hafnium oxide, the dopant included in the ferroelectric material film may include, for example, at least one of gadolinium (Gd), silicon (Si), zirconium (Zr), aluminum (Al), or yttrium (Y).

According to some example embodiments, when the dopant is aluminum (Al), the ferroelectric material film may include 3 atomic percent (at %) to 8 at % of aluminum. Here, a ratio of the dopant may be a ratio of aluminum with respect to a sum of hafnium and aluminum.

According to some example embodiments, when the dopant is silicon (Si), the ferroelectric material film may include 2 at % to 10 at % of silicon. When the dopant is yttrium (Y), the ferroelectric material film may include 2 at % to 10 at % of yttrium. When the dopant is gadolinium (Gd), the ferroelectric material film may include 1 at % to 7 at % of gadolinium. When the dopant is zirconium (Zr), the ferroelectric material film may include 50 at % to 80 at % of zirconium.

According to some example embodiments, the paraelectric material film may have the paraelectric property. The paraelectric material film may include, for example, at least one of silicon oxide and metal oxide with high permittivity. For example, the metal oxide included in the paraelectric material film may include, but is not limited to, at least one of hafnium oxide, zirconium oxide, and aluminum oxide.

According to some example embodiments, the ferroelectric material film and the paraelectric material film may include an identical material. While the ferroelectric material film may have the ferroelectric property, the paraelectric material film may not have the ferroelectric property. For example, when the ferroelectric material film and the paraelectric material film include hafnium oxide, a crystal structure of hafnium oxide included in the ferroelectric material film is different from a crystal structure of hafnium oxide included in the paraelectric material film.

According to some example embodiments, the ferroelectric material film may have a thickness with the ferroelectric property. For example, the thickness of the ferroelectric material film may be, but is not limited to, 0.5 nanometers (nm) to 10 nm. Since a threshold thickness representing the ferroelectric property may vary for each ferroelectric material, the thickness of the ferroelectric material film may vary depending on ferroelectric materials.

As an example, the gate insulating layer 130 may include one ferroelectric material film. As another example, the gate insulating layer 130 may include a plurality of ferroelectric material films spaced apart from each other. For example, the gate insulating layer 130 may have a stacked layer structure in which a plurality of ferroelectric material films and a plurality of paraelectric material films are stacked alternately.

According to some example embodiments, the gate spacer 140 may be disposed on a sidewall of the gate electrode 120. The gate spacer 140 may not be disposed between the fin-type pattern 101 and the first sheets ST1 and between the first sheets ST1 adjacent in the first direction D1. In the semiconductor device according to some example embodiments, the gate spacer 140 may include an outer spacer alone.

According to some example embodiments, the gate spacer 140 includes an insulating material. For example, the gate spacer may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or a combination thereof. The gate spacer 140 is illustrated as a single layer, merely for convenience of description, but is not limited thereto.

According to some example embodiments, the gate capping layer 125 may be disposed on the gate electrode 120 and the gate spacer 140. An upper surface of the gate capping layer 125 may be placed on the same plane as an upper surface of a second interlayer insulating layer 192. Unlike the drawings, the gate capping layer 125 may be disposed between the gate spacers 140. In these cases, the upper surface of the gate capping layer 125, an upper surface of the gate spacer 140, and the upper surface of the second interlayer insulating layer 192 may be placed on the same plane.

According to some example embodiments, the gate capping layer 125 includes an insulating material. For example, the gate capping layer 125 may include, for example, at least one of silicon nitride (SiN), silicon oxynitride (SiON), silicon carbonitride (SiCN), silicon oxycarbonitride (SiOCN), or a combination thereof. The gate capping layer 125 may include a material having an etch selectivity with respect to the second interlayer insulating layer 192.

According to some example embodiments, the first source/drain pattern 150 and the second source/drain pattern 250 may be disposed in the active region AR. The first source/drain pattern 150 and the second source/drain pattern 250 may be arranged in the first direction D1. For example, the first source/drain pattern 150 may be disposed more adjacent to the substrate 100 than the second source/drain pattern 250 in the first direction D1. The second source/drain pattern 250 may be disposed above the first source/drain pattern 150 in the first direction D1.

According to some example embodiments, the first source/drain pattern 150 and the second source/drain pattern 250 may have different conductive types. For example, the first source/drain pattern 150 may have a p-type, and the second source/drain pattern 250 may have an n-type. For example, the first source/drain pattern 150 may include a p-type dopant; and the second source/drain pattern 250 may include an n-type dopant. The p-type dopant may include, but is not limited to, at least one of boron (B) or gallium (Ga). The n-type dopant may include, but is not limited to, at least one of phosphorus (P), arsenic (As), antimony (Sb), or bismuth (Bi). For another example, the first source/drain pattern 150 may have the n-type, and the second source/drain pattern 250 may have the p-type.

According to some example embodiments, the first source/drain pattern 150 may be connected to the first active pattern AP1. The first source/drain pattern 150 may be disposed between the first active patterns AP1 in the second direction D2. The first source/drain pattern 150 may be disposed between the gate electrodes 120 adjacent in the second direction D2. The first source/drain pattern 150 may be disposed on the fin-type pattern 101.

According to some example embodiments, the first source/drain pattern 150 may be a source/drain of a p-type metal-oxide-semiconductor (PMOS) transistor. The first source/drain pattern 150 may be a source/drain of a transistor using the first active pattern AP1 as a channel region.

According to some example embodiments, at least a portion of the first source/drain pattern 150 may increase in a width of the third direction D3 as being farther from the substrate 100 in the first direction D1. Specifically, a portion of the first source/drain pattern 150 overlapping the fin-type pattern 101 in the third direction D3 may increase in a width of the third direction D3 as being farther from the substrate 100 in the first direction D1.

According to some example embodiments, the semiconductor device may include the fence layer 300. The fence layer 300 may surround the first source/drain pattern 150.

According to some example embodiments, in the third direction D3, the first source/drain pattern 150 may be disposed between the fence layers 300. For example, a sidewall of the first source/drain pattern 150 disposed in the third direction D3 may be in contact with the fence layer 300. The sidewall of the first source/drain pattern 150 disposed in the third direction D3 may be surrounded by the fence layer 300. The first source/drain pattern 150 may overlap the fence layer 300 in the third direction D3.

According to some example embodiments, the first source/drain pattern 150 may protrude more than the fence layer 300 toward the second source/drain pattern 250 in the first direction D1. For example, in the first direction D1, with respect to the substrate 100, an upper surface 150US of the first source/drain pattern may be disposed above an upper surface of the fence layer 300.

According to some example embodiments, the first source/drain pattern 150 may include a multilayer. The first source/drain pattern 150 may include a 1-1th source/drain layer 151 and a 1-2th source/drain layer 152. For example, the 1-1th source/drain layer 151 and the 1-2th source/drain layer 152 may include silicon-germanium. In these cases, each of the 1-1th source/drain layer 151 and the 1-2th source/drain layer 152 may include germanium at a different ratio. For another example, the 1-1th source/drain layer 151 and the 1-2th source/drain layer 152 may include a doped p-type impurity. In these cases, each of the 1-1th source/drain layer 151 and the 1-2th source/drain layer 152 may include the impurity at a different concentration. For example, a concentration of a first impurity contained in the 1-1th source/drain layer 151 may be greater than that of the first impurity contained in the 1-2th source/drain layer 152.

According to some example embodiments, the 1-1th source/drain layer 151 on the fin-type pattern 101 may be disposed along a surface of a recess 150R of the first source/drain pattern. For example, the 1-1th source/drain layer 151 may be conformally formed along the surface of the recess 150R of the first source/drain pattern. The recess 150R of the first source/drain pattern may decrease in a width of the third direction D3 as being closer to the substrate 100. The 1-1th source/drain layer 151 may have a U-shape. The 1-1th source/drain layer 151 may have a shape convexly curving toward the substrate 100. The 1-1th source/drain layer 151 may surround at least a portion of the 1-2th source/drain layer 152. The 1-1th source/drain layer 151 may cover at least a portion of a sidewall of the 1-2th source/drain layer 152. For example, the 1-1th source/drain layer 151 may entirely cover a sidewall of the 1-2th source/drain layer 152 disposed in the second direction D2 and cover a portion of a sidewall of the 1-2th source/drain layer 152 disposed in the third direction D3.

According to some example embodiments, the 1-2th source/drain layer 152 may be disposed on the 1-1th source/drain layer 151. The 1-2th source/drain layer 152 may fill the recess 150R of the first source/drain pattern on the 1-1th source/drain layer 151.

According to some example embodiments, the second source/drain pattern 250 may be connected to the second active pattern AP2. The second source/drain pattern 250 may be disposed between the second active patterns AP2 in the second direction D2. The second source/drain pattern 250 may be disposed between the gate electrodes 120 adjacent in the second direction D2. The second source/drain pattern 250 may be disposed above a first interlayer insulating layer 191. The second source/drain pattern 250 may be spaced apart from the first source/drain pattern 150 in the first direction D1.

According to some example embodiments, the second source/drain pattern 250 may be a source/drain of an n-type metal-oxide-semiconductor (NMOS) transistor. The second source/drain pattern 250 may be a source/drain of a transistor using the second active pattern AP2 as a channel region.

According to some example embodiments, the second source/drain pattern 250 may include a multilayer. The second source/drain pattern 250 may include a 2-1th source/drain layer 251 and a 2-2th source/drain layer 252. For example, the 2-1th source/drain layer 251 and the 2-2th source/drain layer 252 may include silicon phosphide or silicon arsenide. In these cases, each of the 2-1th source/drain layer 251 and the 2-2th source/drain layer 252 may include phosphoric acid or arsenic at a different ratio. For example, the first source/drain pattern 150 may include one of a p-type impurity or an n-type impurity, and the second source/drain pattern 250 may include a different one of the p-type impurity or the n-type impurity. For example, when the first source/drain pattern 150 includes a p-type impurity, the second source/drain pattern 250 may include an n-type impurity. For another example, the 2-1th source/drain layer 251 and the 2-2th source/drain layer 252 may contain impurities different from those contained in the 1-1th source/drain layer 151 and the 1-2th source/drain layer 152. The 2-1th source/drain layer 251 and the 2-2th source/drain layer 252 may include a doped n-type impurity. In these cases, each of the 2-1th source/drain layer 251 and the 2-2th source/drain layer 252 may include the impurity at a different concentration. For example, the concentration of a second impurity contained in the 2-1th source/drain layer 251 may be greater than that contained in the 2-2th source/drain layer 252.

According to some example embodiments, on a cross-section including the first direction D1 and the third direction D3, a sidewall of the second source/drain pattern 250 may be surrounded by a second source/drain etch stop layer 162. For example, on the cross-section including the first direction D1 and the third direction D3, whereas the fence layer 300 is disposed on the sidewall of the first source/drain pattern 150, the sidewall of the second source/drain pattern 250 may be in contact with the second source/drain etch stop layer 162 without a separate fence layer.

According to some example embodiments, in the third direction D3, a width W250 of the second source/drain pattern may be greater than a width W150 of the first source/drain pattern. This may be because no separate fence layer is disposed on the sidewall of the second source/drain pattern 250, while the fence layer 300 is disposed on the sidewall of the first source/drain pattern 150 on the cross-section including the first direction D1 and the third direction D3.

According to some example embodiments, in the first direction D1, a height H150 of the first source/drain pattern may be greater than a height H250 of the second source/drain pattern. In these cases, the height H150 of the first source/drain pattern may refer to a distance between a lowermost point of the first source/drain pattern 150 that is most adjacent to the substrate 100 and an uppermost point of the first source/drain pattern 150 that is disposed to be spaced most apart from the substrate 100 in the first direction D1. Similarly, the height H250 of the second source/drain pattern may refer to a distance between a lowermost point of the second source/drain pattern 250 that is most adjacent to the substrate 100 and an uppermost point of the second source/drain pattern 250 that is disposed to be spaced most apart from the substrate 100 in the first direction D1.

According to some example embodiments, since the height H150 of the first source/drain pattern is relatively large, the 1-2th source/drain layer 152 of the first source/drain pattern 150 may also be formed on the 1-1th source/drain layer 151 to be deep enough to overlap the first active pattern AP1 in the second direction D2. As the 1-2th source/drain layer 152 sufficiently overlaps the first active pattern AP1 in the second direction D2, a channel strain may be effectively applied to the first active pattern AP1.

According to some example embodiments, a first source/drain etch stop layer 161 and the first interlayer insulating layer 191 may be disposed above the first source/drain pattern 150. The first source/drain etch stop layer 161 may extend along the upper surface 150US of the first source/drain pattern, a side surface of the fence layer 300, and the upper surface of the field insulating layer 105. In addition, the first source/drain etch stop layer 161 may extend along the gate insulating layer 130 disposed between the first sheets ST1 and the second sheets ST2, which are adjacent in the first direction D1.

According to some example embodiments, the first source/drain etch stop layer 161 may not extend along the sidewall of the first source/drain pattern 150 and may extend along a perimeter of the fence layer 300.

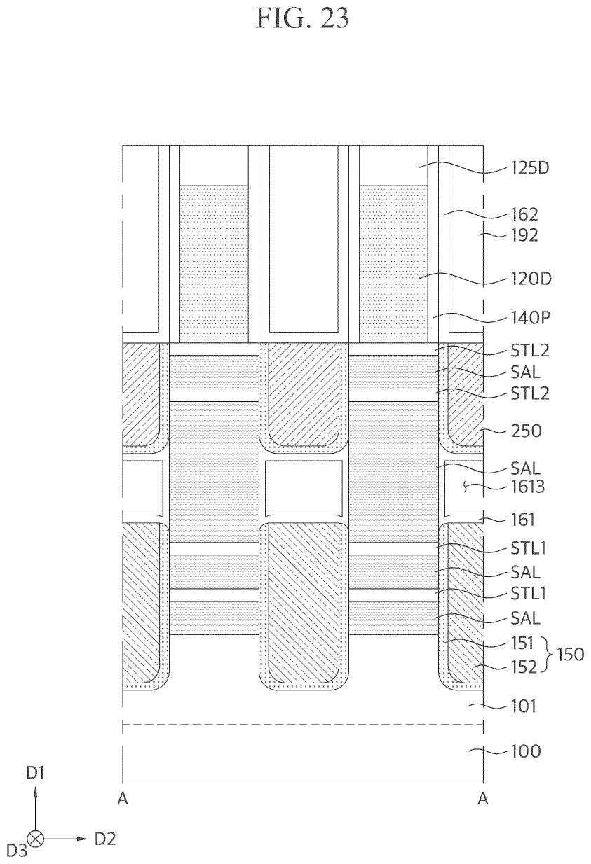

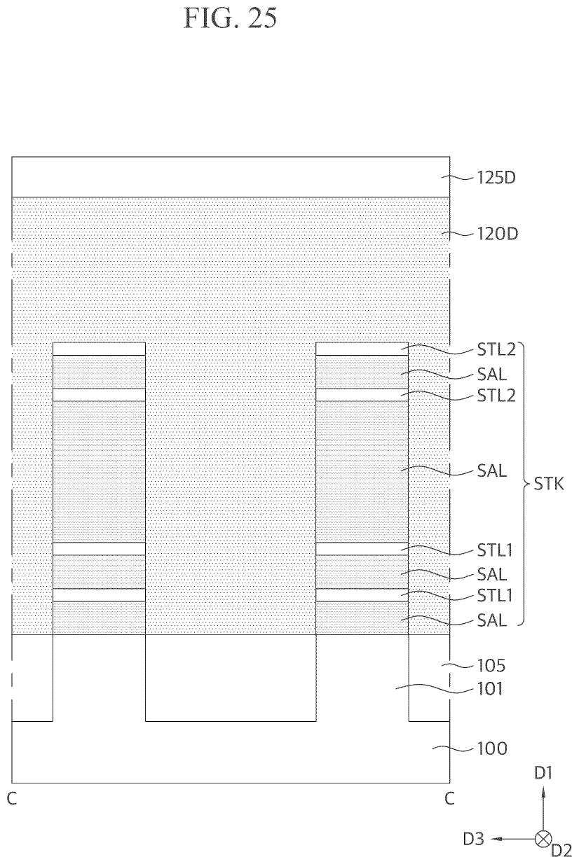

According to some example embodiments, the first source/drain etch stop layer 161 includes a material with etch selectivity with reference to, e.g., a dummy gate (e.g., 120D of FIGS. 23 and 25) and/or a dummy capping layer (e.g., 125D of FIGS. 23 and 25), described in more detail below. For example, the first source/drain etch stop layer 161 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), or a combination thereof.

According to some example embodiments, the first source/drain etch stop layer 161 may be disposed between the first source/drain pattern 150 and the second source/drain pattern 250. The first source/drain etch stop layer 161 may be referred to as an “etch stop layer.” The etch stop layer 161 may be disposed between the fence layer 300 and the second source/drain pattern 250. The etch stop layer 161 may support the second source/drain pattern 250.

According to some example embodiments, the etch stop layer 161 may include a perimeter wall 1618. The perimeter wall 1618 may be a portion of the etch stop layer 161. The perimeter wall 1618 may surround the fence layer 300. The perimeter wall 1618 may be disposed more outward than the fence layer 300 with respect to the first source/drain pattern 150. The perimeter wall 1618 may extend along an outer side surface of the fence layer 300 in the first direction D1 to be connected to a first etch stop portion 1611. The perimeter wall 1618 may overlap the second source/drain pattern 250 in the first direction D1. The second source/drain pattern 250 may be spaced apart from the perimeter wall 1618 in the first direction D1.

According to some example embodiments, the first etch stop layer 161 may include the first etch stop portion 1611 and a second etch stop portion 1612. The first etch stop portion 1611 and the second etch stop portion 1612 may be spaced apart in the first direction D1. The first etch stop portion 1611 may be disposed above the first source/drain pattern 150. The first etch stop portion 1611 may be disposed above the fence layer 300. The second etch stop portion 1612 may be spaced apart above the first etch stop portion 1611 therefrom. The second etch stop portion 1612 may be disposed below the second source/drain pattern 250.

According to some example embodiments, the semiconductor device may include a space 1613 formed between the first etch stop portion 1611 and the second etch stop portion 1612. The space 1613 may be formed between the first source/drain pattern 150 and the second source/drain pattern 250. The space 1613 may be formed between the fence layer 300 and the second source/drain pattern 250. The space 1613 may refer to a space surrounded by the etch stop layer 161.

According to some example embodiments, the first interlayer insulating layer 191 may be formed above the field insulating layer 105. In the first direction D1, the first interlayer insulating layer 191 may be disposed between the first source/drain pattern 150 and the second source/drain pattern 250. The first interlayer insulating layer 191 may cover a lower surface 250BS of the second source/drain pattern.

According to some example embodiments, the first interlayer insulating layer 191 includes an insulating material. For example, according to some examples, the first interlayer insulating layer 191 may include, for example, at least one of silicon oxide, silicon nitride, silicon oxynitride, and a low-permittivity material. For example, the low-permittivity material may include, but is not limited to, fluorinated tetraethyl orthosilicate (FTEOS), hydrogen silsesquioxane (HSQ), bis-benzocyclobutene (BCB), tetramethyl orthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof.

According to some example embodiments, the second source/drain etch stop layer 162 and the second interlayer insulating layer 192 may be disposed above the second source/drain pattern 250. The second source/drain etch stop layer 162 may extend along an upper surface of the second source/drain pattern 250, the sidewall of the second source/drain pattern 250, and an upper surface of the first interlayer insulating layer 191. The second interlayer insulating layer 192 may not cover an upper surface of the gate structure GS. For example, the upper surface of the second interlayer insulating layer 192 may be placed on the same plane as the upper surface of the gate structure GS.

In addition to the above description, the description of the second source/drain etch stop layer 162 and the second interlayer insulating layer 192 is substantially identical to the description of the first source/drain etch stop layer 161 and the first interlayer insulating layer 191 and thus omitted.

According to some example embodiments, a first source/drain contact 171 may be disposed on the first source/drain pattern 150. The first source/drain contact 171 may be connected to the first source/drain pattern 150. The first source/drain contact 171 may penetrate the first interlayer insulating layer 191 and the first source/drain etch stop layer 161 to be connected to the first source/drain pattern 150. In the first direction D1, the first source/drain contact 171 may not entirely penetrate the first interlayer insulating layer 191. The first source/drain contact 171 may be buried within the first interlayer insulating layer 191.

According to some example embodiments, the first source/drain contact 171 may include a first source/drain contact barrier layer 171a and a first source/drain contact filling layer 171b on the first source/drain contact barrier layer 171a. The first source/drain contact barrier layer 171a may extend along a sidewall and a bottom surface of the first source/drain contact filling layer 171b.

According to some example embodiments, with respect to an upper surface of the substrate 100, an upper surface of the first source/drain contact barrier layer 171a is illustrated to be positioned at a substantially identical height to an upper surface of the first source/drain contact filling layer 171b but is not limited thereto. Unlike the drawings, with respect to the upper surface of the substrate 100, the upper surface of the first source/drain contact barrier layer 171a may be lower than the upper surface of the first source/drain contact filling layer 171b.

According to some example embodiments, the first source/drain contact barrier layer 171a may include a conductor, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a two-dimensional (2D) material. In the semiconductor device according to some example embodiments, the 2D material may be a metallic material and/or a semiconductor material. The 2D material may include a 2D allotrope or a 2D compound and, for example, may include at least one of graphene, molybdenum disulfide (MoS2), molybdenum diselenide (MoSe2), tungsten diselenide (WSe2), and tungsten disulfide (WS2) but is not limited thereto. In other words, since the 2D materials described above are enumerated merely for example, the 2D material that may be included in the semiconductor device of the present disclosure is not limited to the aforementioned materials.

According to some example embodiments, the first source/drain contact filling layer 171b may include, for example, at least one of aluminum (Al), tungsten (W), cobalt (Co), ruthenium (Ru), silver (Ag), gold (Au), manganese (Mn), or molybdenum (Mo).

According to some example embodiments, the first source/drain contact 171 is illustrated to include a plurality of conductive layers but is not limited thereto. Unlike the drawings, the first source/drain contact 171 may also be a single layer.

According to some example embodiments, a second source/drain contact 172 may be disposed on the second source/drain pattern 250. The second source/drain contact 172 may be connected to the second source/drain pattern 250. The second source/drain contact 172 may penetrate the second interlayer insulating layer 192 and the second source/drain etch stop layer 162 to be connected to the second source/drain pattern 250. In the first direction D1, the second source/drain contact 172 may entirely penetrate the second interlayer insulating layer 192.

According to some example embodiments, the second interlayer insulating layer 192 may not cover an upper surface of the second source/drain contact 172. As an example, the upper surface of the second source/drain contact 172 may not protrude above the upper surface of the gate structure GS. The upper surface of the second source/drain contact 172 may be placed on the same plane as the upper surface of the gate structure GS. Unlike the drawings, as another example, the upper surface of the second source/drain contact 172 may protrude above the upper surface of the gate structure GS.

According to some example embodiments, the second source/drain contact 172 may include a second source/drain contact barrier layer 172a and a second source/drain contact filling layer 172b on the second source/drain contact barrier layer 172a. The second source/drain contact barrier layer 172a may extend along a sidewall and a bottom surface of the second source/drain contact filling layer 172b. The description of the second source/drain contact barrier layer 172a and the second source/drain contact filling layer 172b is substantially identical to the description of the first source/drain contact barrier layer 171a and the first source/drain contact filling layer 171b and thus omitted.

According to some example embodiments, the fence layer 300 may be disposed on the sidewall of the first source/drain pattern 150 in the third direction D3. The fence layer 300 may overlap the field insulating layer 105 in the first direction D1. The fence layer 300 may prevent an increase in a width of the first source/drain pattern 150, when formed by epitaxial growth, in the third direction D3.

According to some example embodiments, in the third direction D3, the fence layer 300 may be disposed between the first source/drain pattern 150 and the etch stop layer 161. For example, an inner side surface of the fence layer 300 may be in contact with the first source/drain pattern 150, and the outer side surface of the fence layer 300 may be in contact with the perimeter wall 1618 of the etch stop layer 161.

According to some example embodiments, the fence layer 300 may be formed at an identical (or substantially similar) level with the gate spacer 140. In these cases, being formed at an identical level may indicate being formed by an identical manufacturing process. The fence layer 300 may include an identical material to the gate spacer 140. For example, the fence layer 300 may include an insulating material, such as at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or a combination thereof.

According to some example embodiments, the etch stop layer 161 may be disposed to surround the fence layer 300. For example, the perimeter wall 1618 may be disposed to surround the fence layer 300. The perimeter wall 1618 may be in contact with the outer side surface of the fence layer 300 in the third direction D3. The etch stop layer 161 may include a nitride material.

According to some example embodiments, each of the fence layer 300 and the etch stop layer 161 may include a different material. For example, the fence layer 300 may include silicon oxycarbide (SiOC), and the perimeter wall 1618 may include silicon nitride (SiN).

According to some example embodiments, a first etch stop layer 196, a third interlayer insulating layer 193, a second etch stop layer 197, and a fourth interlayer insulating layer 194 may be disposed above the second interlayer insulating layer 192, the gate structure GS, and the second source/drain contact 172. The first etch stop layer 196, the third interlayer insulating layer 193, the second etch stop layer 197, and the fourth interlayer insulating layer 194 may be sequentially stacked on the second interlayer insulating layer 192, the gate structure GS, and the second source/drain contact 172 in the first direction D1.

According to some example embodiments, the first etch stop layer 196 may include a material having an etch selectivity with respect to the third interlayer insulating layer 193. For example, the first etch stop layer 196 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), aluminum oxide (AlO), aluminum nitride (AlN), aluminum oxycarbide (AlOC), or a combination thereof. The first etch stop layer 196 is illustrated as a single layer but is not limited thereto. Unlike the drawings, the first etch stop layer 196 may also not be formed. For example, the third interlayer insulating layer 193 may include at least one of silicon oxide, silicon nitride, silicon carbonitride, silicon oxynitride, and a low-permittivity material.

According to some example embodiments, the second etch stop layer 197 may be disposed between the third interlayer insulating layer 193 and the fourth interlayer insulating layer 194. The second etch stop layer 197 may extend along an upper surface of the third interlayer insulating layer 193. The second etch stop layer 197 may include a material having an etch selectivity with respect to the fourth interlayer insulating layer 194. The description of a material included in the second etch stop layer 197 may be substantially identical to the description of the first etch stop layer 196. The description of the fourth interlayer insulating layer 194 may be substantially identical to the description of the third interlayer insulating layer 193.

According to some example embodiments, a gate contact 180 may be disposed on the gate electrode 120. The gate contact 180 may penetrate the gate capping layer 125 to be connected to the gate electrode 120. The gate contact 180 may penetrate the first etch stop layer 196 and the third interlayer insulating layer 193. The gate contact 180 may be connected to a wiring line 201.

As an example, an upper surface of the gate contact 180 may protrude above the upper surface of the gate structure GS. Unlike the drawings, as another example, the upper surface of the gate contact 180 may be placed on the same plane as the upper surface of the gate structure GS.

According to some example embodiments, the gate contact 180 may include a gate contact barrier layer 180a and a gate contact filling layer 180b on the gate contact barrier layer 180a. The description of materials included in the gate contact barrier layer 180a and the gate contact filling layer 180b may be identical to the description of materials included in the first source/drain contact barrier layer 171a and the first source/drain contact filling layer 171b.

According to some example embodiments, a wiring via 175 may be disposed within the third interlayer insulating layer 193. The wiring via 175 may penetrate the first etch stop layer 196 to be directly connected to the second source/drain contact 172. The wiring via 175 may connect the second source/drain contact 172 and the wiring line 201. Although not illustrated, the wiring via 175 may penetrate the third interlayer insulating layer 193, the first etch stop layer 196, the second interlayer insulating layer 192, the second source/drain etch stop layer 162, the first interlayer insulating layer 191, and the first source/drain etch stop layer 161 to be connected to the first source/drain contact 171.

According to some example embodiments, the wiring via 175 may include a via barrier layer 175a and a via filling layer 175b. The via barrier layer 175a may extend along a sidewall and a bottom surface of the via filling layer 175b. For example, the via barrier layer 175a may include a conductive material, such as at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a 2D material. For example, the via filling layer 175b may include at least one of aluminum (Al), tungsten (W), cobalt (Co), ruthenium (Ru), copper (Cu), silver (Ag), gold (Au), manganese (Mn), or molybdenum (Mo).

According to some example embodiments, the wiring line 201 may be disposed within the fourth interlayer insulating layer 194. The wiring line 201 may be connected to the gate contact 180. The wiring line 201 may be connected to the first source/drain contact 171 or the second source/drain contact 172 through the wiring via 175.

According to some example embodiments, the wiring line 201 may include a wiring barrier layer 201a and a wiring filling layer 201b. For example, the wiring barrier layer 201a may include at least one of metal, conductive metal nitride, conductive metal carbide, conductive metal oxide, conductive metal carbonitride, and a 2D material. For example, the wiring filling layer 201b may include at least one of metal and metal alloy. The description of the wiring barrier layer 201a and the wiring filling layer 201b of the wiring line 201 may be substantially identical to the description of the via barrier layer 175a and the via filling layer 175b of the wiring via 175. The wiring line 201 is illustrated to have a conductive multilayer structure but is not limited thereto. Unlike the drawings, the wiring line 201 may have a single conductive layer structure.

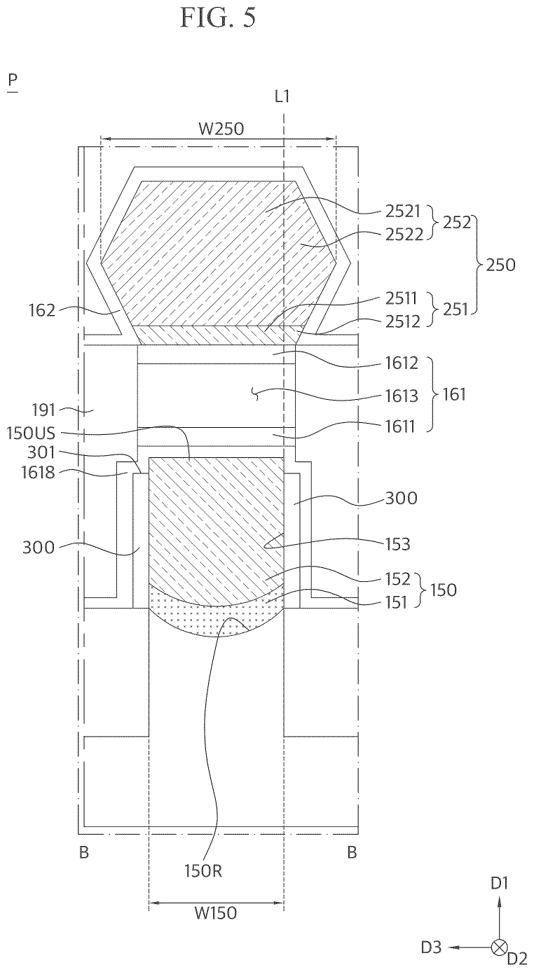

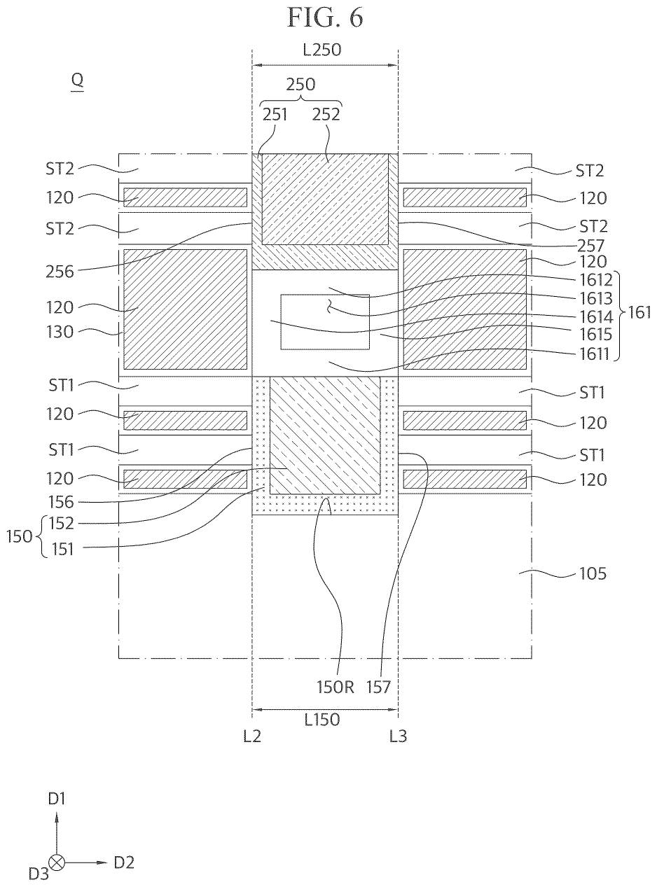

FIG. 5 is an example enlarged view showing part P of FIG. 3. FIG. 6 is an example enlarged view showing part Q of FIG. 2. The description of elements with reference to FIGS. 1 to 4 may be the same as (or substantially similar to) to the description of elements illustrated in FIGS. 5 and 6.

According to some example embodiments, a first width W150 of the first source/drain pattern 150 in the third direction D3 may be less than a second width W250 of the second source/drain pattern 250 in the third direction D3. The second source/drain pattern 250 may have a more extended width than the first source/drain pattern 150 in the third direction D3. Since the second width W250 of the second source/drain pattern 250 is greater than the first width W150 of the first source/drain pattern 150, the electrical resistance of the second source/drain pattern 250 may be less than the electrical resistance of the first source/drain pattern 150. The second width W250 of the second source/drain pattern 250 greater than the first width W150 of the first source/drain pattern 150 may be because the fence layer 300 only surrounds the first source/drain pattern 150 among the first and second source/drain patterns 150 and 250.

According to some example embodiments, the first source/drain pattern 150 and the second source/drain pattern 250 may overlap in the first direction D1. At least a portion of the second source/drain pattern 250 may not overlap the first source/drain pattern 150 in the first direction D1. For example, the first source/drain pattern 150 may include a first source/drain side surface 153, and with respect to a reference line L1 extending along the first source/drain side surface 153 in the first direction D1, the second source/drain pattern 250 may protrude outside the reference line L1.

According to some example embodiments, the second source/drain pattern 250 may include the 2-1th source/drain layer 251 and the 2-2th source/drain layer 252. The description of the 2-1th source/drain layer 251 and the 2-2th source/drain layer 252 with reference to FIGS. 1 to 4 may be the same as (or substantially similar to) to the description of the 2-1th source/drain layer 251 and the 2-2th source/drain layer 252 shown in FIGS. 5 and 6.

According to some example embodiments, the second source/drain pattern 250 may include 2-1th source/drain portions 2511 and 2521. The 2-1th source/drain portions 2511 and 2521 may overlap the first source/drain pattern 150 in the first direction D1. The 2-1th source/drain portions 2511 and 2521 may be a portion of the second source/drain pattern 250 overlapping the first source/drain pattern 150 in the first direction D1. The 2-1th source/drain portions 2511 and 2521 may be a portion of the second source/drain pattern 250 positioned in the third direction D3 with respect to the reference line L1.

According to some example embodiments, the 2-1th source/drain portions 2511 and 2521 may include a 1-1th layer portion 2511 and a 2-1th layer portion 2521. The 1-1th layer portion 2511 may be a portion of the 2-1th source/drain layer 251 overlapping the first source/drain pattern 150 in the first direction D1. The 2-1th layer portion 2521 may be a portion of the 2-2th source/drain layer 252 overlapping the first source/drain pattern 150 in the first direction D1.

According to some example embodiments, the second source/drain pattern 250 may include 2-2th source/drain portions 2512 and 2522. The 2-2th source/drain portions 2512 and 2522 may not overlap the first source/drain pattern 150 in the first direction D1. The 2-2th source/drain portions 2512 and 2522 may be a portion of the second source/drain pattern 250 not overlapping the first source/drain pattern 150 in the first direction D1. The 2-2th source/drain portions 2512 and 2522 may be a portion of the second source/drain pattern 250 positioned in a direction opposite to the third direction D3 with respect to the reference line L1.

According to some example embodiments, the 2-2th source/drain portions 2512 and 2522 may include a 1-2th layer portion 2512 and a 2-2th layer portion 2522. The 1-2th layer portion 2512 may be a portion of the 2-1th source/drain layer 251 not overlapping the first source/drain pattern 150 in the first direction D1. The 2-2th layer portion 2522 may be a portion of the 2-2th source/drain layer 252 not overlapping the first source/drain pattern 150 in the first direction D1.

According to some example embodiments, the first source/drain pattern 150 may be surrounded by the fence layer 300, and the second source/drain pattern 250 may not be surrounded by the fence layer 300. The first source/drain pattern 150, as surrounded by the fence layer 300, may have the first width W150 in the third direction D3, which is equal to a distance between the fence layers 300. The second source/drain pattern 250, as not surrounded by the fence layer 300, may have a width in the third direction D3, which is not limited but may be extended to the second width W250. The fence layer 300 may be formed in a cylindric shape around the first source/drain pattern 150. In this case, the first source/drain pattern 150 may have the first width W150 in the third direction D3, which is equal to an inner diameter of the fence layer 300.

According to some example embodiments, the second source/drain pattern 250 may overlap the fence layer 300 in the first direction D1. The fence layer 300 may include a fence end portion 301 disposed toward the second source/drain pattern 250 in the first direction D1. The second source/drain pattern 250 may be spaced apart from the fence end portion 301 in the first direction D1.

According to some example embodiments, the 2-1th source/drain portions 2511 and 2521 does not overlap the fence layer 300 in the first direction D1. The 2-1th source/drain portions 2511 and 2521 may overlap the first source/drain pattern 150 in the first direction D1 and may not overlap the fence layer 300 in the first direction D1.

According to some example embodiments, the 2-2th source/drain portions 2512 and 2522 may overlap the fence layer 300 in the first direction D1. The 2-2th source/drain portions 2512 and 2522 may not overlap the first source/drain pattern 150 in the first direction D1 and may overlap the fence layer 300 in the first direction D1.

According to some example embodiments, the etch stop layer 161 may be disposed between the first source/drain pattern 150 and the second source/drain pattern 250. The description of the etch stop layer 161 with reference to FIGS. 1 to 4 may be the same as (or substantially similar to) the description of the etch stop layer 161 shown in FIGS. 5 and 6.

According to some example embodiments, the etch stop layer 161 may be disposed above the first source/drain pattern 150 and may be disposed below the second source/drain pattern 250. The etch stop layer 161 may be surrounded by the first interlayer insulating layer 191. The etch stop layer 161 may be disposed between the fence layer 300 and the second source/drain pattern 250. The etch stop layer 161 may be disposed above the fence layer 300.

According to some example embodiments, the etch stop layer 161 may include the first etch stop portion 1611 and the second etch stop portion 1612. The description of the first etch stop portion 1611 and the second etch stop portion 1612 with reference to FIGS. 1 to 4 may be the same as (or substantially similar to) to the description of the first etch stop portion 1611 and the second etch stop portion 1612 shown in FIGS. 5 and 6.

According to some example embodiments, the first etch stop portion 1611 may be disposed between the fence layer 300 and the second source/drain pattern 250. The second etch stop portion 1612 may be disposed between the first etch stop portion 1611 and the second source/drain pattern 250. The second etch stop portion 1612 may be spaced apart from the first etch stop portion 1611 in the first direction D1. The second etch stop portion 1612 may support the second source/drain pattern 250.

According to some example embodiments, the space 1613 may be formed between the first etch stop portion 1611 and the second etch stop portion 1612. The space 1613 may be a space surrounded by the etch stop layer 161. The space 1613 may be formed between the first source/drain pattern 150 and the second source/drain pattern 250.

According to some example embodiments, the etch stop layer 161 may include the perimeter wall 1618. The description of the perimeter wall 1618 with reference to FIGS. 1 to 4 may be the same as (or substantially similar to) to the description of the perimeter wall 1618 shown in FIGS. 5 and 6. For example, the perimeter wall 1618 may surround the fence layer 300 and may be connected to the first etch stop portion 1611.

According to some example embodiments, a first length L150 of the first source/drain pattern 150 in the second direction D2 and a second length L250 of the second source/drain pattern 250 in the second direction D2 may be substantially identical.

According to some example embodiments, the first source/drain pattern 150 may include a 1-1th edge 156 and a 1-2th edge 157. The 1-1th edge 156 and the 1-2th edge 157 may be spaced apart in the second direction D2. The first source/drain pattern 150 may have the first length L150 from the 1-1th edge 156 to the 1-2th edge 157.

According to some example embodiments, the second source/drain pattern 250 may include a 2-1th edge 256 and a 2-2th edge 257. The 2-1th edge 256 and the 2-2th edge 257 may be spaced apart in the second direction D2. The second source/drain pattern 250 may have the second length L250 from the 2-1th edge 256 to the 2-2th edge 257.

According to some example embodiments, the first length L150 and the second length L250 may be substantially identical. The 1-1th edge 156 and the 2-1th edge 256 may be aligned along a first boundary line L2 extending in the first direction D1. The 1-2th edge 157 and the 2-2th edge 257 may be aligned along a second boundary line L3 extending in the first direction D1. The first length L150 may refer to a length between the first boundary line L2 and the second boundary line L3. The second length L250 may refer to a length between the first boundary line L2 and the second boundary line L3.

According to some example embodiments, the etch stop layer 161 may have a length substantially identical (substantially similar) to the lengths L150 and L250 of the first and second source/drain patterns 150 and 250 in the second direction D2. The etch stop layer 161 may be disposed between the first boundary line L2 and the second boundary line L3.

According to some example embodiments, the etch stop layer 161 may include a third etch stop portion 1614 and a fourth etch stop portion 1615. The third etch stop portion 1614 and the fourth etch stop portion 1615 may be spaced apart in the second direction D2. Each of the third etch stop portion 1614 and the fourth etch stop portion 1615 may extend in the first direction D1 to connect the first etch stop portion 1611 and the second etch stop portion 1612. The space 1613 may be surrounded by the first, second, third, and fourth etch stop portions 1611, 1612, 1614, and 1615.

According to some example embodiments, the third etch stop portion 1614 may be aligned with the 1-1th edge 156 and the 2-1th edge 256 along the first boundary line L2. The fourth etch stop portion 1615 may be aligned with the 1-2th edge 157 and the 2-2th edge 257 along the second boundary line L3.

According to some example embodiments, the first source/drain pattern 150 may be disposed between the plurality of first sheets ST1 spaced apart from each other in the second direction D2. The first source/drain pattern 150 may be disposed between the gate electrodes 120 spaced apart from each other in the second direction D2. The first source/drain pattern 150 may extend to the first length L150 in the second direction D2 to connect the plurality of first sheets ST1 spaced apart from each other in the second direction D2.

According to some example embodiments, the second source/drain pattern 250 may be disposed between the plurality of second sheets ST2 spaced apart from each other in the second direction D2. The second source/drain pattern 250 may be disposed between the gate electrodes 120 spaced apart from each other in the second direction D2. The second source/drain pattern 250 may extend to the second length L250 in the second direction D2 to connect the plurality of second sheets ST2 spaced apart from each other in the second direction D2.

According to some example embodiments, the etch stop layer 161 may be disposed between the gate electrodes 120 spaced apart from each other in the second direction D2.

According to some example embodiments, edges of the plurality of first sheets ST1 and edges of the plurality of second sheets ST2, which are spaced apart from each other in the first direction D1, may be aligned along the first boundary line L2. The edges of the plurality of first sheets ST1 and the edges of the plurality of second sheets ST2, which are spaced apart from each other in the first direction D1, may be aligned along the second boundary line L3.

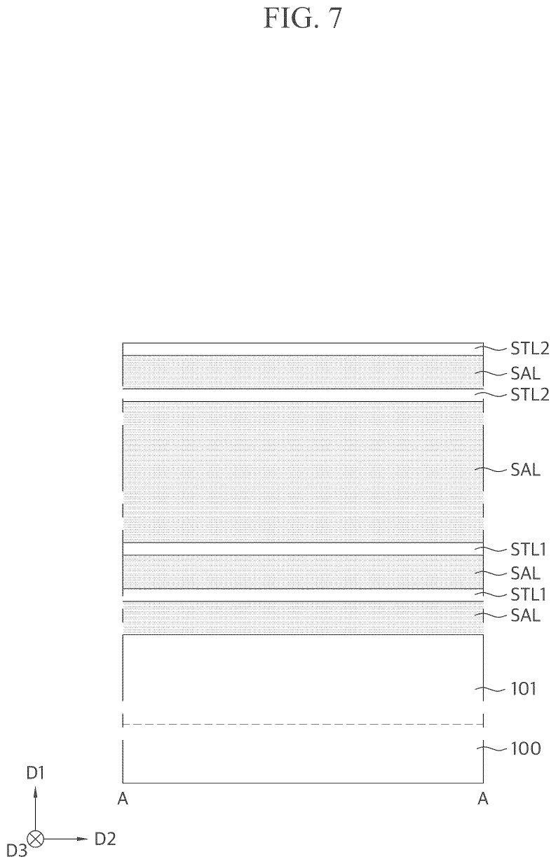

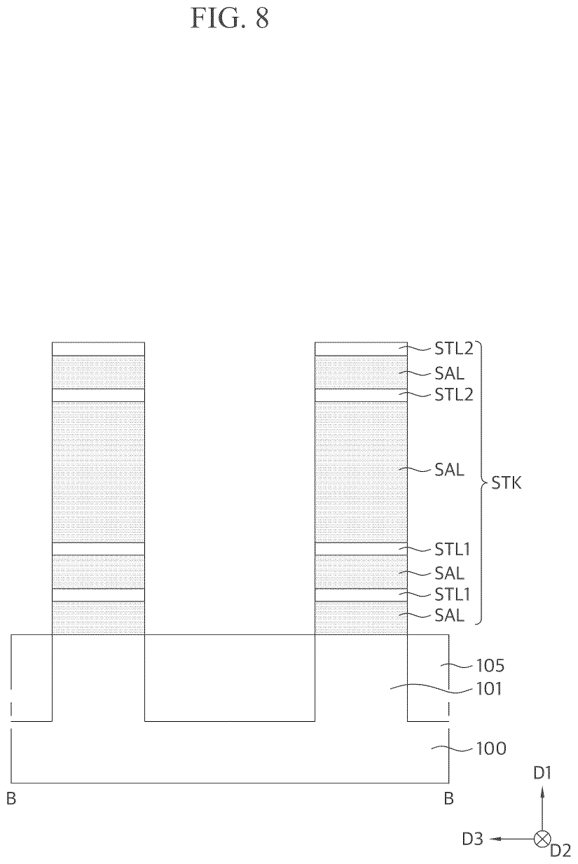

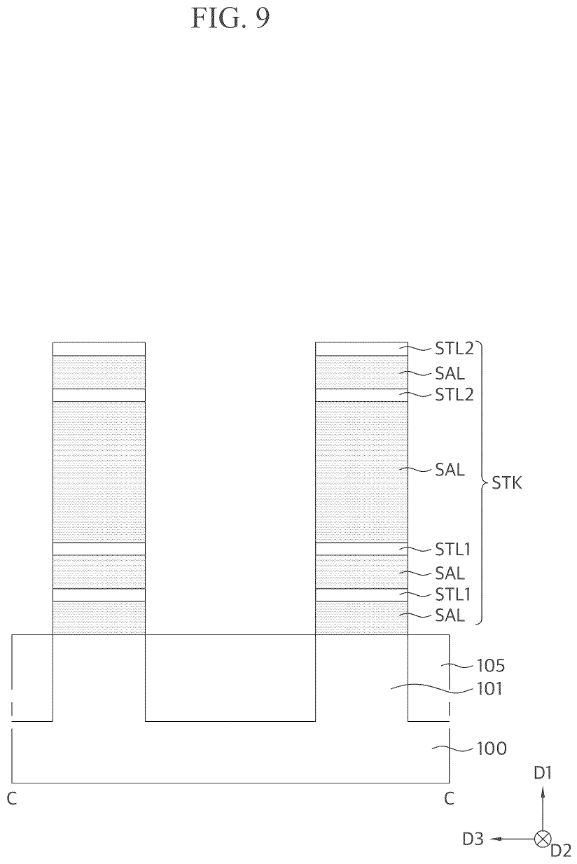

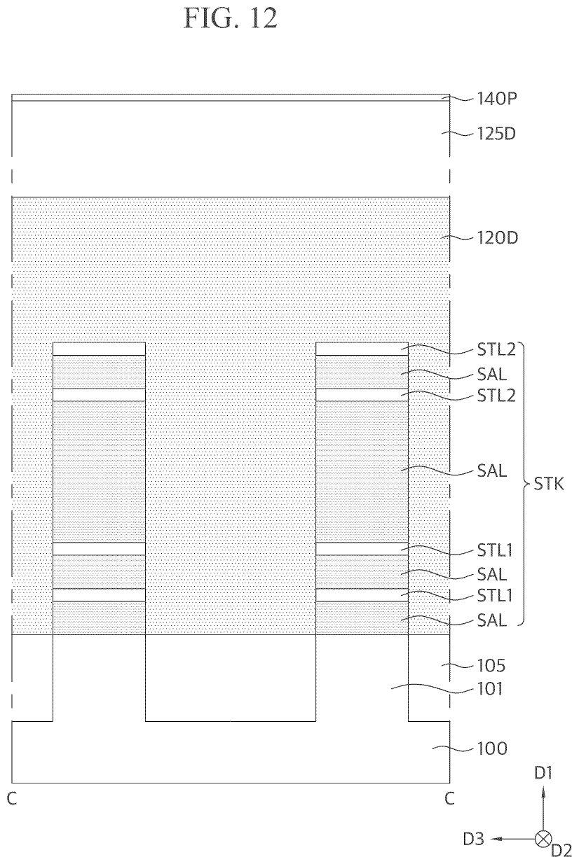

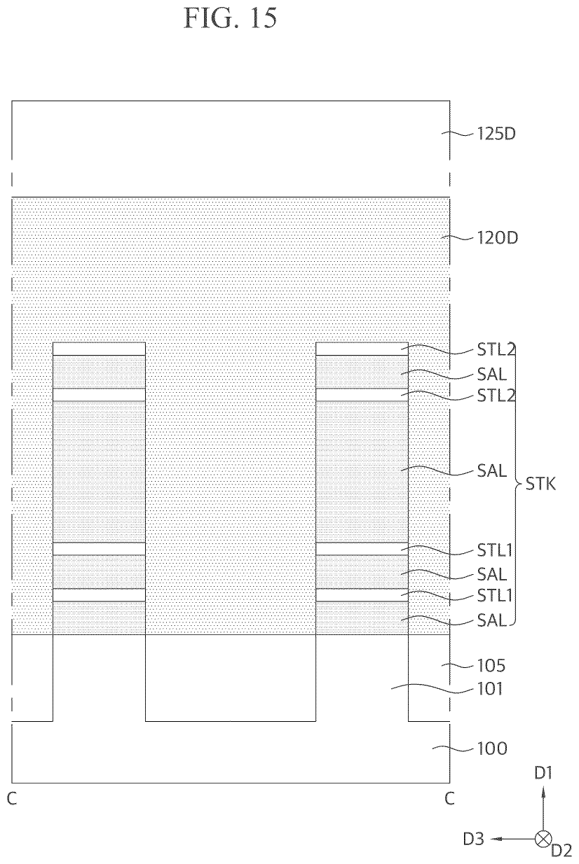

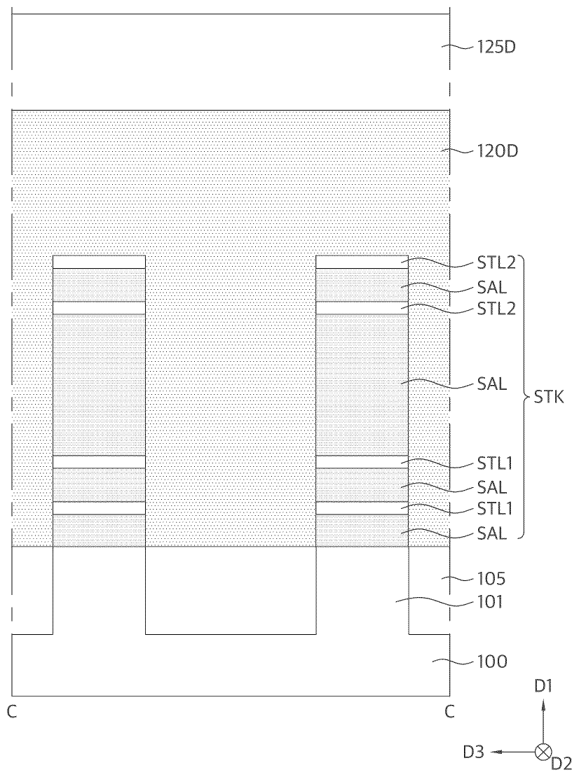

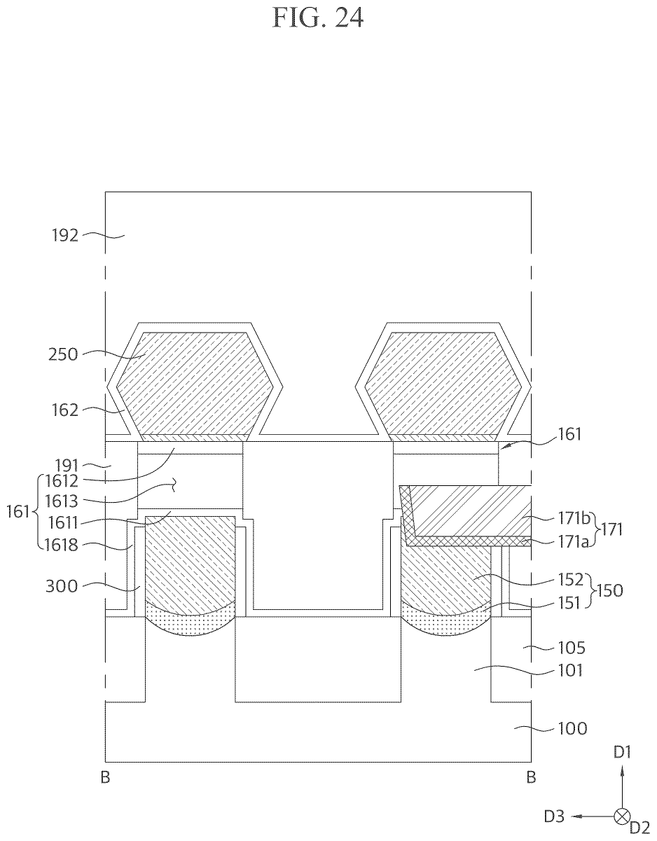

FIGS. 7 to 29 are example diagrams of intermediate operations for illustrating a method of manufacturing a semiconductor device according to some example embodiments. For reference, FIGS. 7 to 29 are diagrams illustrating a semiconductor device in intermediate operations based on a method of manufacturing the semiconductor device illustrated in FIGS. 2 to 6.

Referring to FIGS. 7 to 9, a first sheet layer STL1 and a sacrificial layer SAL may be alternately stacked on the substrate 100 and the fin-type pattern 101, and a second sheet layer STL2 and the sacrificial layer SAL may be alternately stacked.

Specifically, a stacked structure STK, in which the first sheet layer STL1 and the sacrificial layer SAL are alternately stacked, and the second sheet layer STL2 and the sacrificial layer SAL are alternately stacked, may be formed on the substrate 100 of the active region AR of FIG. 1. The stacked structure STK may not be formed on the substrate 100 of the field region FR of FIG. 1, in which the field insulating layer 105 is disposed. Accordingly, the upper surface of the field insulating layer 105 may be exposed between the stacked structures STK. In other words, when viewed in the first direction D1, the stacked structures STK may be formed to extend in the second direction D2 and to be spaced apart in the third direction D3.

According to some example embodiments, the first sheet layer STL1 and the second sheet layer STL2 may include an identical material to each other and include a different material from the sacrificial layer SAL. For example, the first sheet layer STL1 and the second sheet layer STL2 may include silicon (Si), and the sacrificial layer SAL may include silicon-germanium (SiGe). However, example embodiments are not limited thereto. In addition, the first sheet layer STL1 and the second sheet layer STL2 may include an identical material to the substrate 100 and the fin-type pattern 101, but example embodiments are not limited thereto.

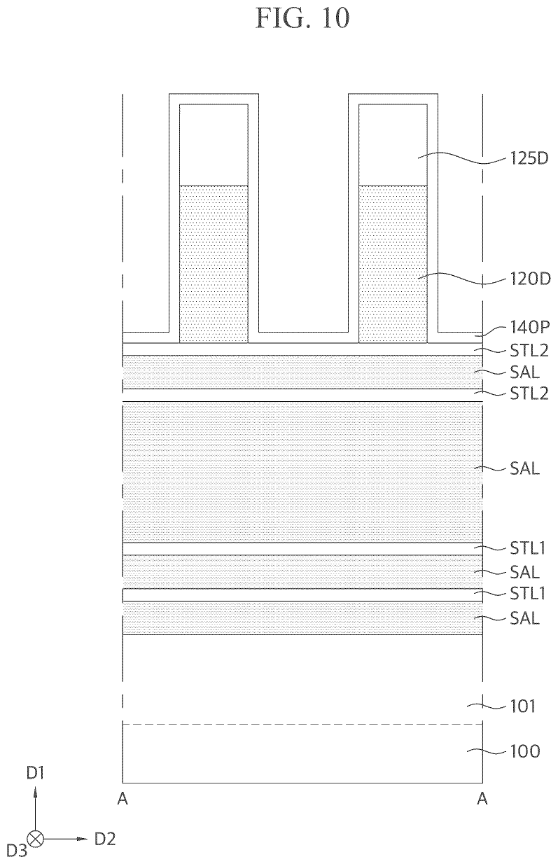

Subsequently, referring to FIGS. 10 to 12, a dummy gate 120D, a dummy capping layer 125D, and a pre-spacer 140P may be formed above the stacked structure STK.

According to some example embodiments, when viewed in the first direction D1, the dummy gates 120D and the dummy capping layers 125D may be formed to extend in the third direction D3 and to be spaced apart in the second direction D2. The dummy gate 120D and the dummy capping layer 125D may intersect the stacked structure STK.

According to some example embodiments, the pre-spacer 140P may be formed along profiles of the dummy gate 120D and the dummy capping layer 125D, the upper surface of the field insulating layer 105, and a profile of the stacked structure STK.

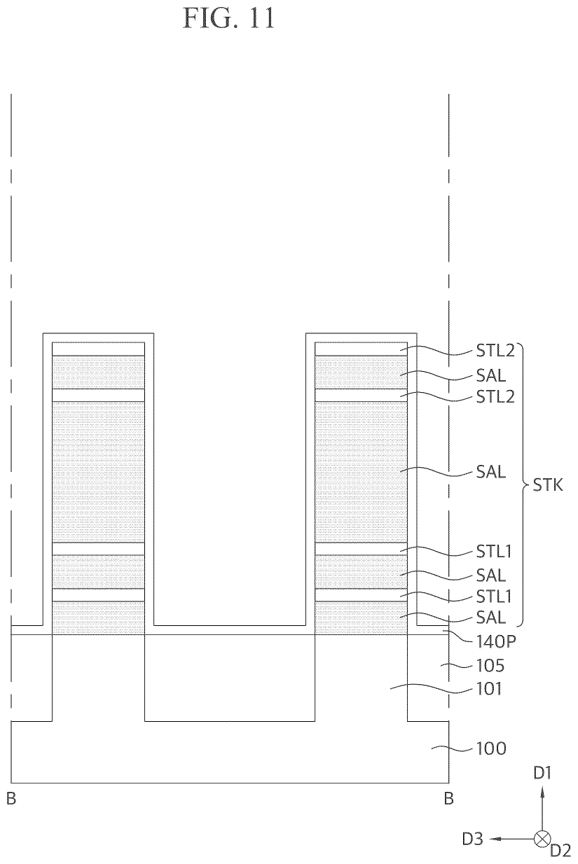

According to some example embodiments, the pre-spacer 140P may be formed on the stacked structure STK even in an area where the dummy gate 120D and the dummy capping layer 125D are not formed. Accordingly, referring to FIG. 11, the pre-spacer 140P may also be formed on the stacked structure STK not intersecting the dummy gate 120D and the dummy capping layer 125D.

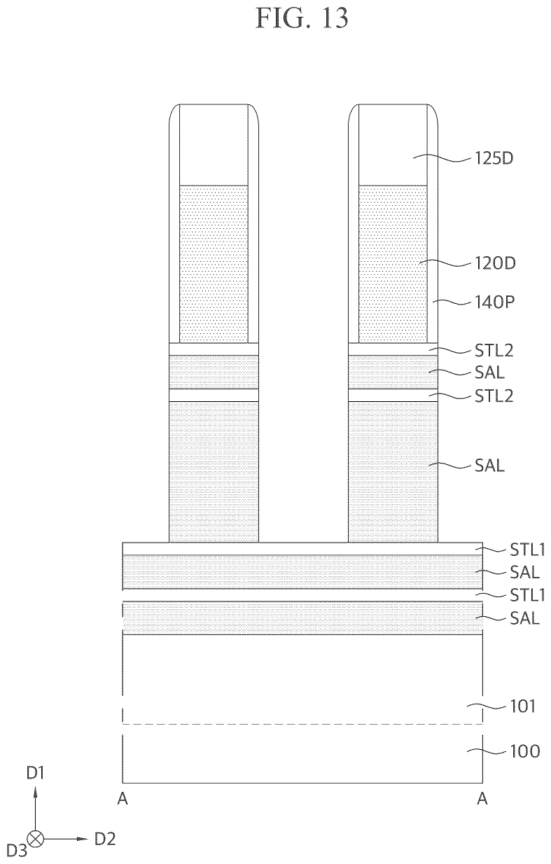

Subsequently, referring to FIGS. 13 to 15, a portion of the second sheet layer STL2 and a portion of the sacrificial layer SAL may be patterned using the dummy gate 120D and the dummy capping layer 125D as a mask.

Specifically, the second sheet layer STL2 and the sacrificial layer SAL disposed above the first sheet layer STL1 may be patterned so that the first sheet layer STL1 disposed uppermost in the first direction D1 is exposed. Since patterning is performed using the dummy gate 120D and the dummy capping layer 125D as a mask, the second sheet layer STL2 and the sacrificial layer SAL not overlapping the dummy gate 120D and the dummy capping layer 125D in the first direction D1 may be removed.

According to some example embodiments, while the portion of the second sheet layer STL2 and the portion of the sacrificial layer SAL are patterned, the pre-spacer 140P of FIG. 10 formed on the dummy gate 120D and the dummy capping layer 125D may be removed.

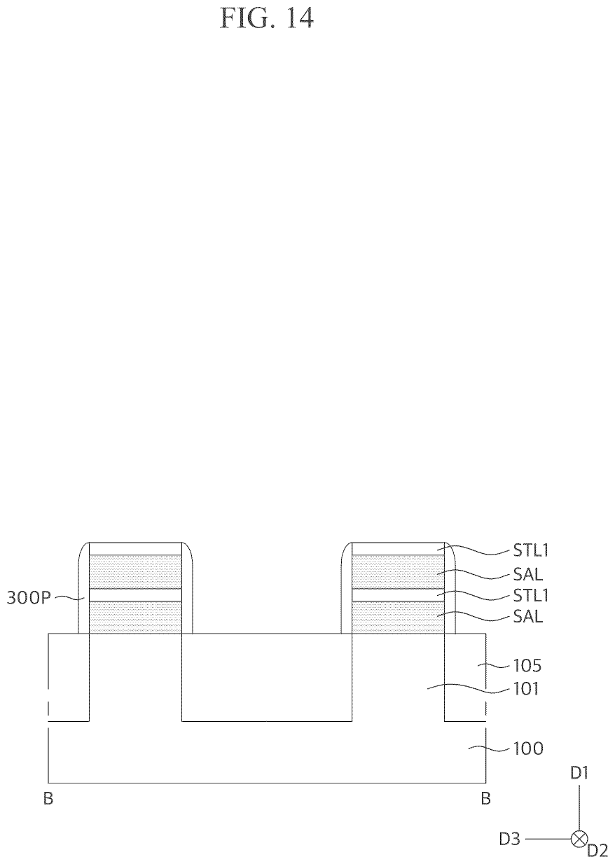

Referring to FIG. 14, in the third direction D3, a structure in which the sacrificial layer SAL and the first sheet layer STL1 are alternately stacked between the stacked structures of the dummy gates 120D and the dummy capping layers 125D may only remain, and the pre-spacer 140P of FIG. 11 formed on the field insulating layer 105 may be removed. As the pre-spacer 140P of FIG. 11 is patterned, a pre-fence layer 300P may be formed on a side surface of the structure in which the sacrificial layer SAL and the first sheet layer STL1 are alternately stacked. In other words, as a portion where the second sheet layer STL2 of FIG. 11 and the sacrificial layer SAL are alternately stacked is patterned, a portion of the pre-spacer 140P of FIG. 11 formed on a side surface of the stacked structure STK of FIG. 11 may be removed. After the portion of the pre-spacer 140P of FIG. 11 formed on the side surface of the stacked structure STK of FIG. 11 is removed, the remaining pre-spacer 140P of FIG. 11 may be the pre-fence layer 300P formed on the side surface of the structure in which the sacrificial layer SAL and the first sheet layer STL1 are alternately stacked. Therefore, in at least some embodiments, the pre-fence layer 300P and the pre-spacer 140P of FIG. 11 may include an identical material.

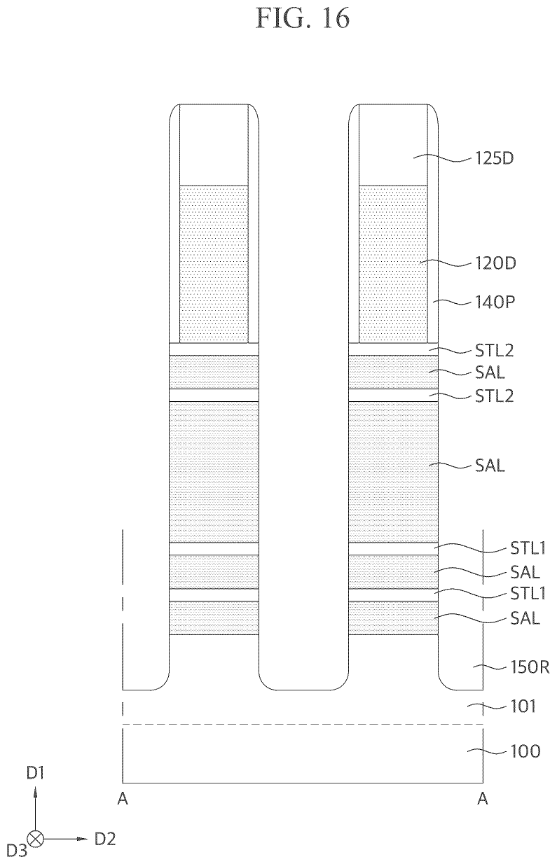

Subsequently, referring to FIGS. 16 to 18, a portion where the first sheet layer STL1 and the sacrificial layer SAL are alternately stacked may be patterned using the dummy gate 120D and the dummy capping layer 125D as a mask again.

According to some example embodiments, as the first sheet layer STL1 and the sacrificial layer SAL, not overlapping the dummy gate 120D and the dummy capping layer 125D, are removed, the recess 150R of the first source/drain pattern may be formed. In the second direction D2, the first sheet layer STL1 may be exposed through the recess 150R of the first source/drain pattern.

According to some example embodiments, while the first sheet layer STL1 of FIG. 14 and the sacrificial layer SAL of FIG. 14 disposed between the pre-fence layers 300P of FIG. 14 in the third direction D3 are removed and the recess 150R of the first source/drain pattern is formed, a portion of the pre-fence layer 300P of FIG. 14 may also be removed. Therefore, when the recess 150R of the first source/drain pattern is formed, the fence layer 300 may be formed. The recess 150R of the first source/drain pattern between the fence layers 300 may be disposed on the fin-type pattern 101.

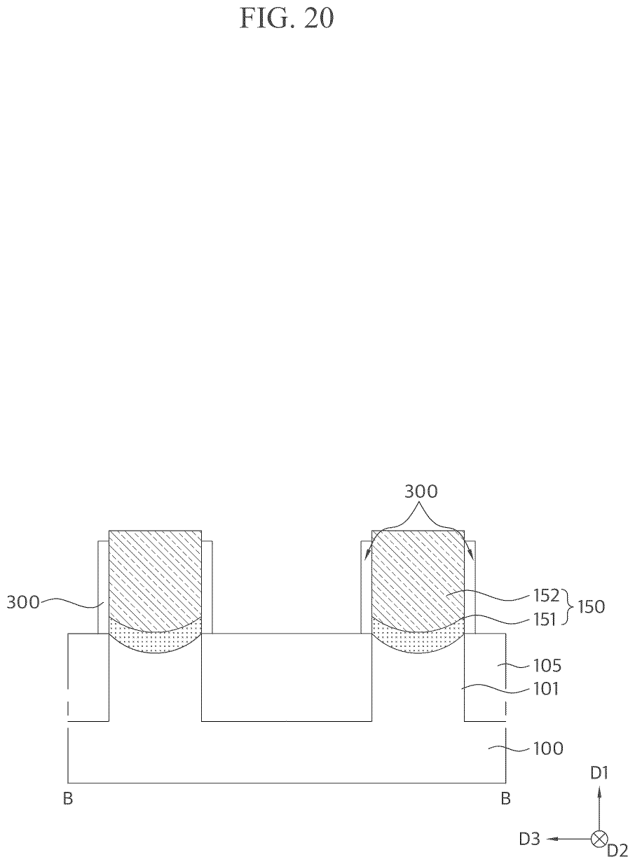

According to some example embodiments, the fence layer 300 may be formed. A plurality of fence layers 300 may be formed to be spaced apart from each other in the third direction D3. A growth space 150S in which the first source/drain pattern 150 of FIG. 20 is epitaxially grown may be formed between the plurality of fence layers 300. The first source/drain pattern 150 may be grown by an epitaxial process within the growth space 150S surrounded by the fence layers 300.

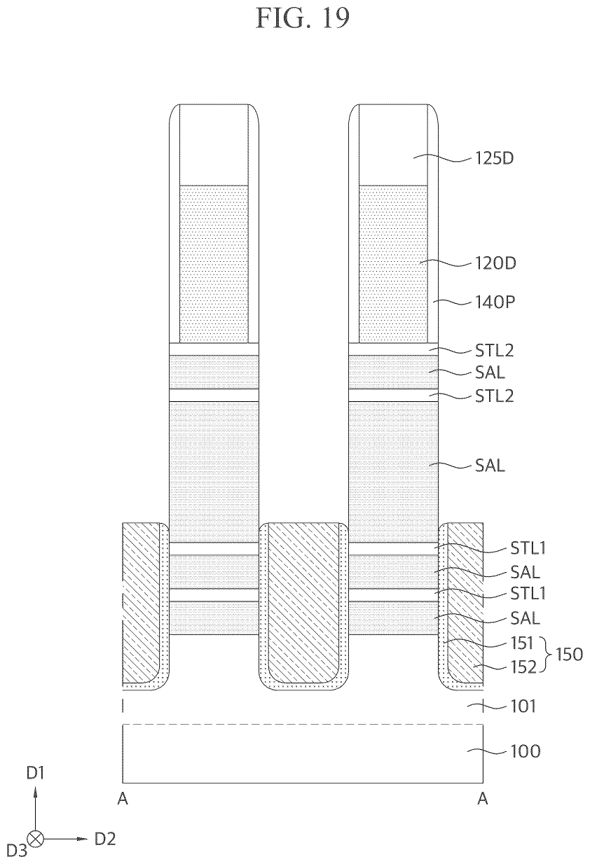

Subsequently, referring to FIGS. 19 and 20, the first source/drain pattern 150 may be formed.

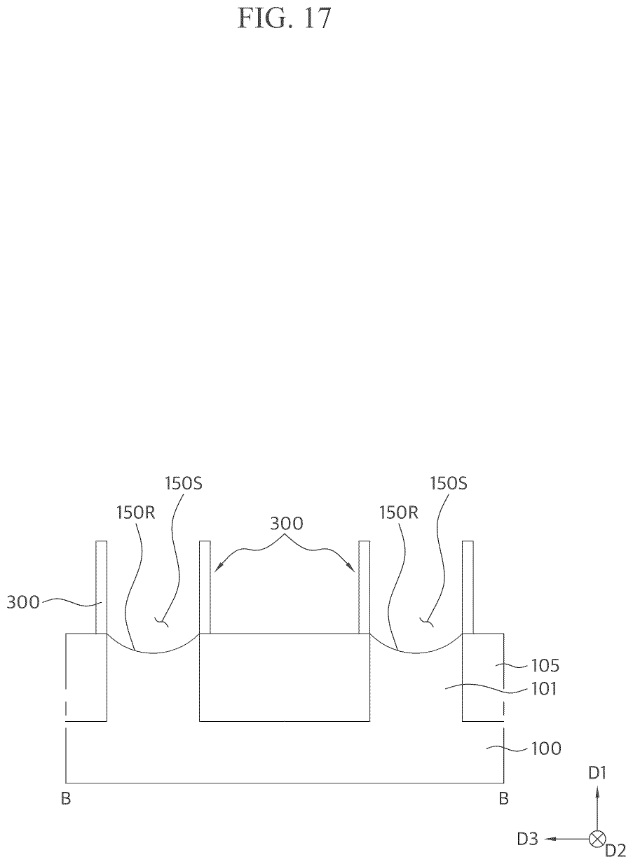

Specifically, the 1-1th source/drain layer 151 and the 1-2th source/drain layer 152 may be formed within the recess 150R of FIGS. 16 and 17 of the first source/drain pattern. The 1-1th source/drain layer 151 and the 1-2th source/drain layer 152 may be formed through the epitaxial growth of a semiconductor material. For example, the 1-1th source/drain layer 151 and the 1-2th source/drain layer 152 may include silicon-germanium. The 1-1th source/drain layer 151 may be formed along a surface of the recess 150R of FIGS. 16 and 17 of the first source/drain pattern formed to be U-shaped on the fin-type pattern 101. Accordingly, the 1-1th source/drain layer 151 may also be formed to be U-shaped.

According to some example embodiments, since the first source/drain pattern 150 is formed between the fence layers 300 in the third direction D3, a width of the first source/drain pattern 150 in the third direction D3 may be formed up to a distance between the fence layers 300.

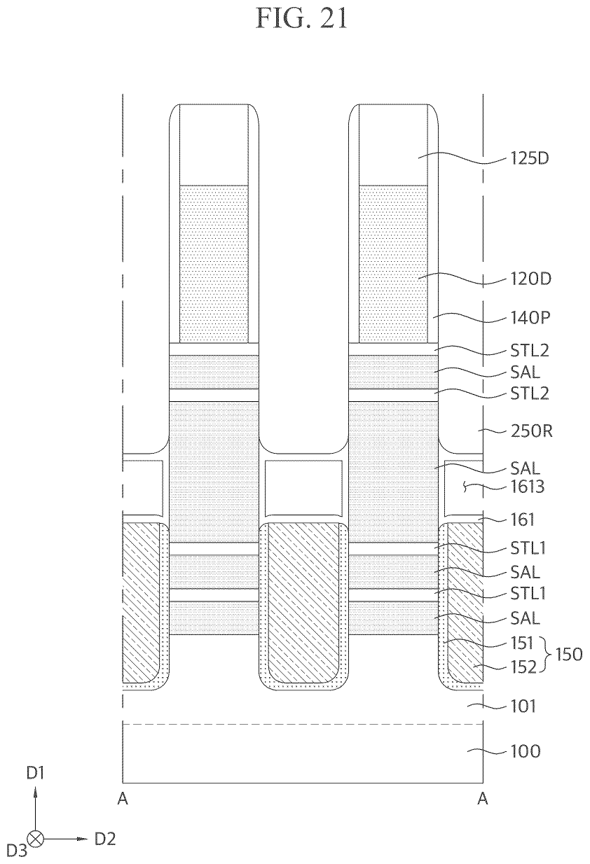

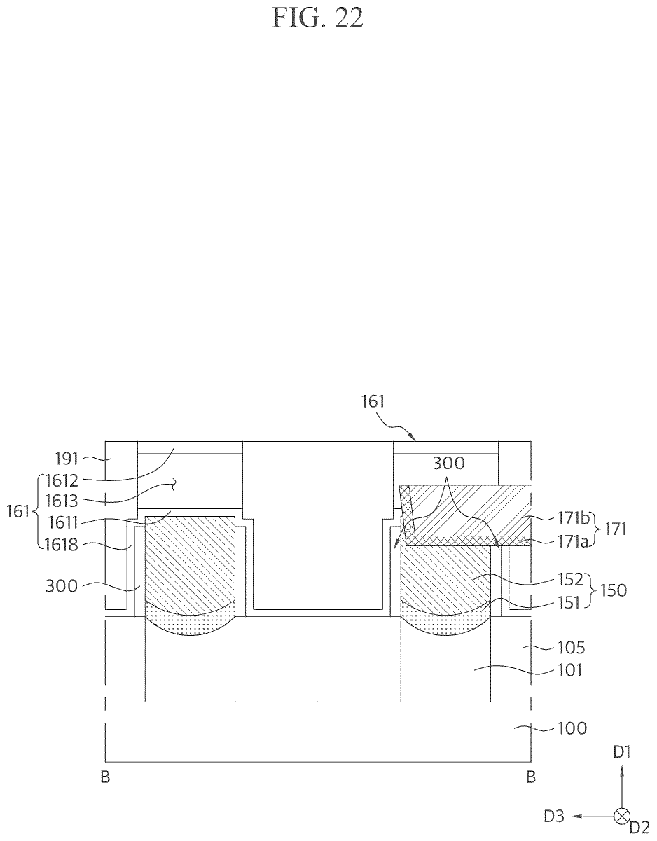

Subsequently, referring to FIGS. 21 and 22, the first source/drain etch stop layer 161 and the first interlayer insulating layer 191 may be formed above the first source/drain pattern 150. In addition, the first source/drain contact 171 connected to the first source/drain pattern 150 may be formed within the first interlayer insulating layer 191. A recess 250R of the second source/drain pattern, to which the second sheet layer STL2 is exposed, may be formed on the first interlayer insulating layer 191.

Subsequently, referring to FIGS. 23 to 25, the second source/drain pattern 250, the second source/drain etch stop layer 162, and the second interlayer insulating layer 192 may be formed.

According to some example embodiments, the second source/drain pattern 250 may fill the recess 250R of FIG. 21 of the second source/drain pattern.

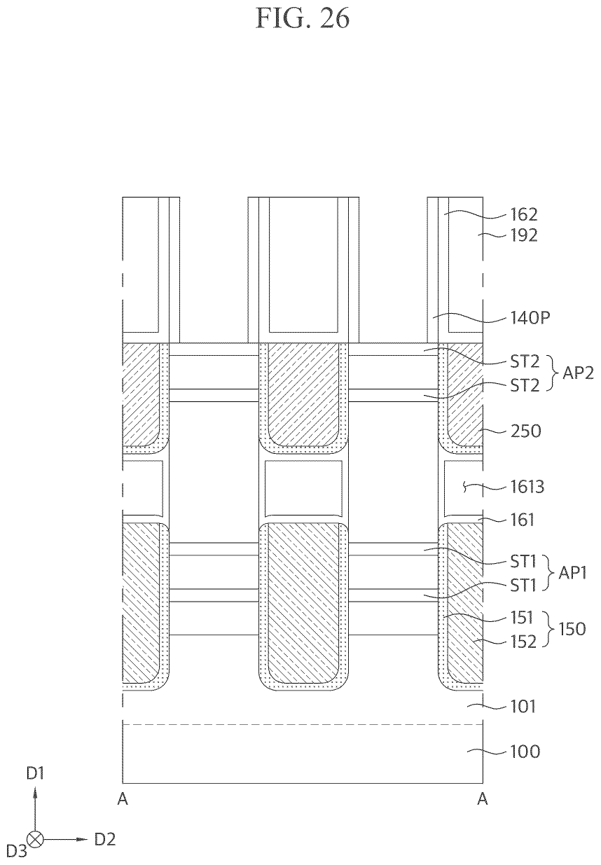

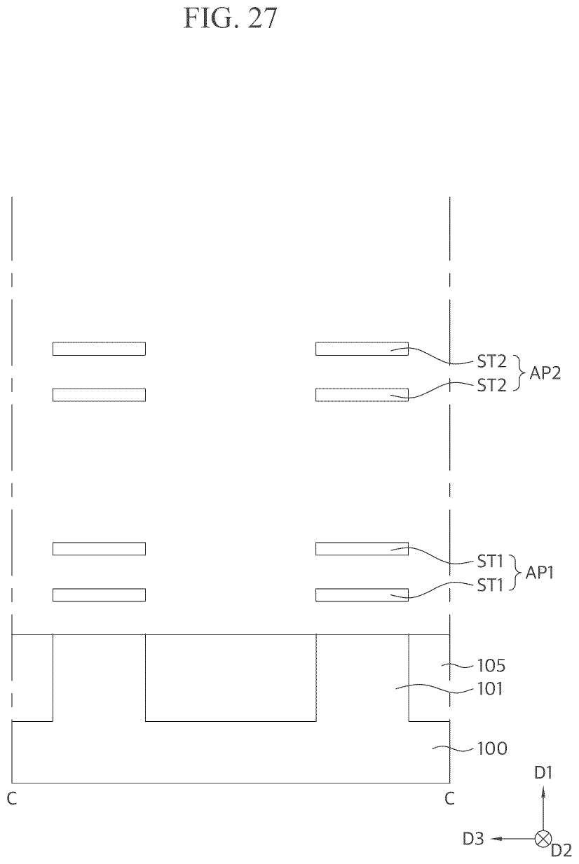

Subsequently, referring to FIGS. 26 and 27, the dummy gate 120D of FIGS. 23 and 25 and the dummy capping layer 125D of FIGS. 23 and 25 may be removed, and the first sheets ST1 and the second sheets ST2 may be formed.

Specifically, while the sacrificial layer SAL of FIGS. 23 and 25 is removed and the sheet layers STL1 and STL2 are exposed, the first sheets ST1 and the second sheets ST2 may be formed. An upper surface and a lower surface of each of the first sheets ST1 connected to the first source/drain pattern 150 may be exposed. An upper surface and a lower surface of each of the second sheets ST2 connected to the second source/drain pattern 250 may be exposed.

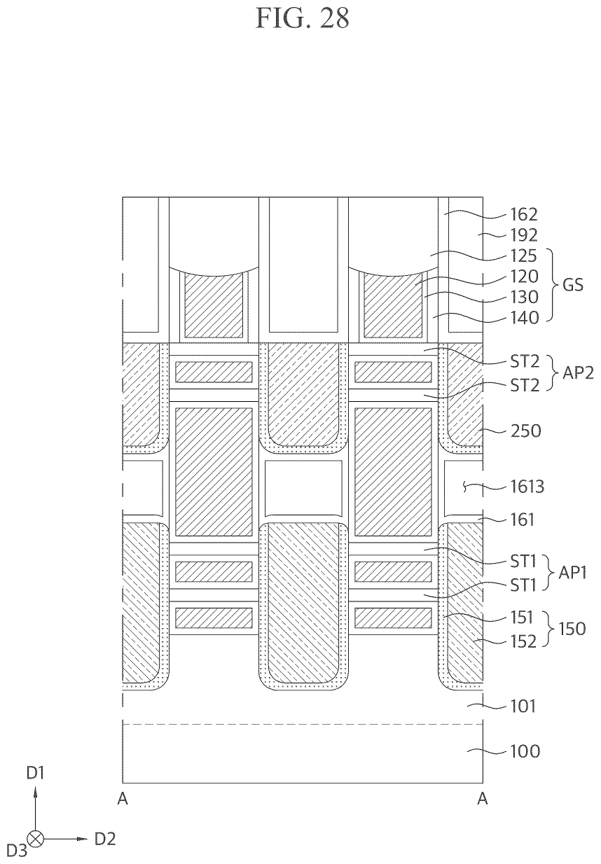

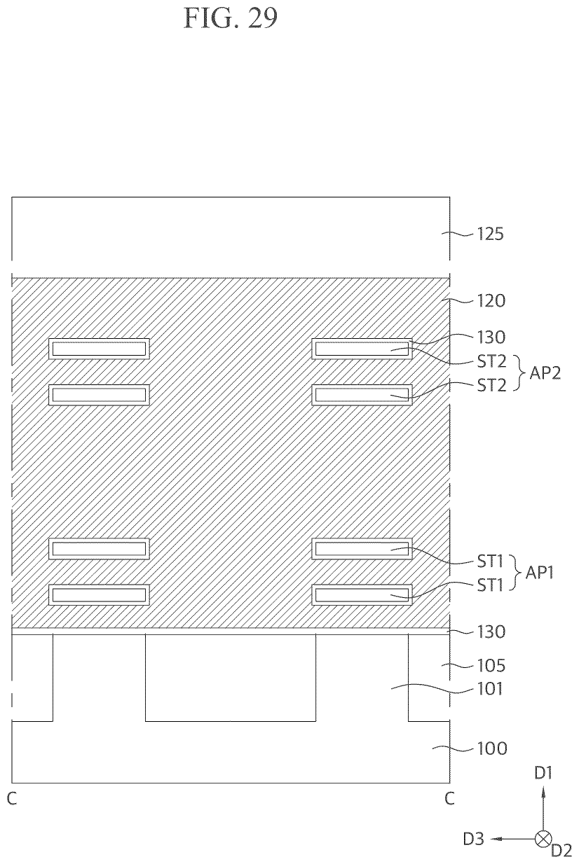

Subsequently, referring to FIGS. 28 and 29, the gate insulating layer 130, the gate electrode 120, and the gate capping layer 125 may be formed.

Specifically, the gate insulating layer 130 and the gate electrode 120 may be formed along surfaces of the first sheets ST1 and the second sheets ST2.

Subsequently, referring to FIGS. 2 to 6, the first etch stop layer 196, the third interlayer insulating layer 193, the second etch stop layer 197, and the fourth interlayer insulating layer 194 may be formed, and the gate contact 180 connected to the gate electrode 120 may be formed.

The method of manufacturing the semiconductor device according to some example embodiments of the present disclosure may include disposing a plurality of first sheet layers to be spaced apart in a first direction intersecting a surface of a substrate.

The method of manufacturing the semiconductor device according to some example embodiments of the present disclosure may include disposing a plurality of second sheet layers spaced apart in the first direction above a plurality of first sheet layers.

The method of manufacturing the semiconductor device according to some example embodiments of the present disclosure may include forming a pre-fence layer surrounding the plurality of first sheet layers.

The method of manufacturing the semiconductor device according to some example embodiments of the present disclosure may include cutting some of the plurality of first sheet layers and a portion of the pre-fence layer and forming a fence layer to form a recess of a first source/drain pattern inside.

The method of manufacturing the semiconductor device according to some example embodiments of the present disclosure may include forming the first source/drain pattern surrounded by the fence layer in the recess of the first source/drain pattern.

The method of manufacturing the semiconductor device according to some example embodiments of the present disclosure may include forming a second source/drain pattern, of which at least a portion overlaps the fence layer, above the first source/drain pattern.

According to some example embodiments of the present disclosure, it is possible to enhance a degree of integration in a semiconductor device.

According to example embodiments of the present disclosure, it is possible to reduce electrical resistance due to an extended width of the source/drain pattern in comparison to a semiconductor device with a source/drain pattern with a reduced width.

While various example embodiments of the present disclosure are described in detail above, the scope of the present disclosure is not limited thereto, and it will be apparent to those of ordinary skill in the art that various modifications and variations may be made without departing from the technical idea of the present disclosure as defined by the appended claims. In addition, the aforementioned example embodiments may be implemented with some elements removed, and each example embodiment may be implemented in combination with each other.

What is claimed is:

1. A semiconductor device comprising:
a first active pattern on a substrate, the first active pattern including a plurality of first sheets, the plurality of first sheets spaced apart from each other in a first direction, the first direction intersecting an upper surface of the substrate;
a second active pattern above the first active pattern, the second active pattern including a plurality of second sheets, the plurality of second sheets spaced apart from each other in the first direction;
a first source/drain pattern connected to the first active pattern in a second direction, the second direction intersecting the first direction;
a second source/drain pattern above the first source/drain pattern and connected to the second active pattern in the second direction;
a gate electrode surrounding the first active pattern and the second active pattern and extending in a third direction, the third direction intersecting the first direction and the second direction; and
a fence layer surrounding at least a portion of the first source/drain pattern,
wherein the at least a portion of the first source/drain pattern surrounded by the fence layer has a first width in the third direction, and the second source/drain pattern is spaced apart from the fence layer and has a second width in the third direction, the second width greater than the first width.

2. The semiconductor device of claim 1, wherein the fence layer overlaps with the second source/drain pattern in the first direction.

3. The semiconductor device of claim 1, wherein the second source/drain pattern includes:
a 2-1th source/drain portion overlapping with the first source/drain pattern in the first direction; and
a 2-2th source/drain portion overlapping with the fence layer in the first direction.

4. The semiconductor device of claim 1, further comprising:
a perimeter wall surrounding the fence layer and overlapping with the second source/drain pattern in the first direction.

5. The semiconductor device of claim 1, further comprising:
a space between the first source/drain pattern and the second source/drain pattern.

6. The semiconductor device of claim 5, further comprising:
an etch stop layer between the first source/drain pattern and the second source/drain pattern, the etch stop layer supporting the second source/drain pattern and surrounding the space between the first source/drain pattern and the second source/drain pattern.

7. The semiconductor device of claim 1, wherein the first source/drain pattern includes:
a 1-1th source/drain layer including a first impurity at a first concentration; and
a 1-2th source/drain layer including the first impurity at a second concentration, the second concentration greater than the first concentration.

8. The semiconductor device of claim 1, wherein the first source/drain pattern includes a first impurity, and
the second source/drain pattern includes,
a 2-1th source/drain layer including a second impurity at a third concentration, the second impurity different from the first impurity and
a 2-2th source/drain layer including the second impurity at a fourth concentration, the fourth concentration greater than the third concentration.

9. The semiconductor device of claim 1, wherein a length of the first source/drain pattern in the second direction is same as a length of the second source/drain pattern in the second direction.

10. The semiconductor device of claim 1, wherein
the first source/drain pattern includes one of a p-type impurity or an n-type impurity, and
the second source/drain pattern includes the other one of the p-type impurity or the n-type impurity.

11. A semiconductor device comprising:
a first active pattern on a substrate, the first active pattern including a plurality of first sheets, the plurality of first sheets spaced apart from each other in a first direction intersecting an upper surface of the substrate;
a second active pattern above the first active pattern, the second active pattern including a plurality of second sheets, the plurality of second sheets spaced apart from each other in the first direction;
a first source/drain pattern connected to the first active pattern in a second direction, the second direction intersecting the first direction;
a second source/drain pattern above the first source/drain pattern and connected to the second active pattern in the second direction;
a gate electrode surrounding the first active pattern and the second active pattern and extending in a third direction, the third direction intersecting with the first direction and the second direction; and
a fence layer surrounding at least a portion of the first source/drain pattern, the fence layer including a fence end portion spaced apart from the second source/drain pattern,
wherein at least a portion of the second source/drain pattern is spaced apart from the fence end portion in the first direction and overlaps with the fence end portion in the first direction.

12. The semiconductor device of claim 11, wherein the second source/drain pattern includes:
a 2-1th source/drain portion overlapping with the first source/drain pattern in the first direction; and
a 2-2th source/drain portion including the portion overlapping with the fence end portion in the first direction.

13. The semiconductor device of claim 11, further comprising:
an etch stop layer surrounding the fence layer,
wherein the second source/drain pattern is supported by the etch stop layer.

14. The semiconductor device of claim 13, further comprising:
a space between the first source/drain pattern and the second source/drain pattern, the space surrounded by the etch stop layer.

15. The semiconductor device of claim 11, wherein a width of the second source/drain pattern in the third direction is greater than distance between the fence layers in the third direction.

16. A semiconductor device comprising:
a first active pattern on a substrate, the first active pattern including a plurality of first sheets, the plurality of first sheets spaced apart from each other in a first direction, the first direction intersecting an upper surface of the substrate;
a second active pattern above the first active pattern, the second active pattern including a plurality of second sheets, the plurality of second sheets spaced apart from each other in the first direction;
a first source/drain pattern connected to the first active pattern in a second direction, the second direction intersecting the first direction;
a second source/drain pattern above the first source/drain pattern and connected to the second active pattern in the second direction;
a gate electrode surrounding the first active pattern and the second active pattern and extending in a third direction, the third direction intersecting the first direction and the second direction; and
a fence layer surrounding the first source/drain pattern and spaced apart from the second source/drain pattern, the fence layer non-overlapping with the second source/drain pattern in the third direction.

17. The semiconductor device of claim 16, wherein the second source/drain pattern overlaps with the fence layer in the first direction.

18. The semiconductor device of claim 16, wherein the fence layer includes a fence end portion spaced apart from the second source/drain pattern in the first direction.

19. The semiconductor device of claim 16, further comprising:
an etch stop layer between the first source/drain pattern and the second source/drain pattern.

20. The semiconductor device of claim 16, wherein the second source/drain pattern has a width in the third direction is greater than distance between of the fence layers in the third direction.
